(19) United States
(12) Patent Application Publication
(10) Pub. No.: US 2008/0145985 A1
(43) Pub. Date: Jun. 19, 2008

(54) EMBEDDED SEMICONDUCTOR MEMORY DEVICES AND METHODS FOR FABRICATING THE SAME

(75) Inventor: Min-hwa CHI, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 11/871,127

(22) Filed: Oct. 11, 2007

(30) Foreign Application Priority Data
Dec. 15, 2006 (CN) 200610147320.5

(51) Int. Cl. H01L 21/8238; H01L 29/94

(52) U.S. Cl. 438/199; 257/369

(57) ABSTRACT

The invention discloses a method for fabricating an embedded semiconductor memory device, comprising: preparing a semiconductor substrate comprising a region IA and a region IB; forming gate dielectric layers and gate structures sequentially on the semiconductor substrate, with the gate dielectric layer in region IA being a charge trap region, and the gate dielectric layer in region IB being a non-charge trap region; forming source/drain extension regions in region IA and region IB of the semiconductor substrate; and forming source/drain regions in region IA and region IB of the semiconductor substrate. There is provided correspondingly an embedded semiconductor memory device. The invention also provides an embedded semiconductor memory device and a method for fabricating the same. A two-bit storage operation can be enabled for the embedded semiconductor memory device according to the invention so as to achieve high-density storage. Furthermore, the process for forming a logic circuit can be compatible with that for forming a memory device circuit according to the invention.

### FIELD OF THE INVENTION

The present invention relates to a field of semiconductor technologies, and more particularly to an embedded semiconductor memory devices and methods for fabricating the same.

### BACKGROUND OF THE INVENTION

A nonvolatile semiconductor memory device, such as flash memory, can store data when the power is off. A flash memory cell can include an electrically isolated floating gate, a source region, a drain region, and a control gate to control the floating gate potential. Typically, the threshold voltage of a flash memory cell is dependent upon the amount of charges stored on the floating gate. The digital data (1 or 0) in a flash memory cell can be represented by the threshold voltage (high or low) of the memory cell.

The integration of flash memory and CMOS logic circuits leads to a System-on-Chip (SoC) with superior system performance and lower overall cost Such SoC or precisely “embedded flash memory” in CMOS is attractive in industry with intention that the widespread CMOS libraries and IP's in CMOS logic technology can also be readily usable for SoC applications. In recent years, SoC or “embedded flash memory” (as interchangeably used in this disclosure) are under active development based on two approaches, i.e., either simply compatible with standard logic CMOS process or stand-alone flash memory process.

In the case of flash memory fabrication based on standard logic CMOS process, the flash memory cells and logic transistors must share same process steps of gate oxide growth, polysilicon/gate stack formation, and spacer formation, . . . etc. As a result, the logic compatible flash memory cell often is large in size, operating at high voltage, and is complicated in array arrangement. Such memory cells can only result in lower memory storage density (e.g. <·0.5 Mb), higher operating voltage, and limitations on circuit performance. This is somewhat defeating the purpose of the embedded flash memory with logic circuits for higher performance and overall lower cost in SoC.

A stand-alone flash memory technology provides small memory cell with high performance due to more process steps added to the basic CMOS logic process flow, e.g. the ETOX flash memory process with a double polysilicon floating gate or a charge trap flash memory technology (such as SONOS, NROM, etc.) with oxide-nitride-oxide multi-layer for charge storage. Although those CMOS transistors based on stand-alone memory flow can also form logic circuits, however, their transistor characteristics are deviated from those based on standard logic CMOS flow due to additional thermal cycles and process steps (compared with logic CMOS process). Therefore, the existing CMOS logic libraries and IP cores can not be compatible and readily usable in those logic circuits based on the stand-along flash memory technologies.

As disclosed in “A novel PHINES flash memory cell with low power program/erase, small pitch, 2-bit per cell for data storage applications”, by Chih Chieh Yeh et. al., IEEE Transactions on Electron Devices, v.52, no.4, p.541-545, 2005, a flash memory cell with nitride serving as charge storage can be erased by injecting hot holes into nitride, and programmed by band-to-band tunneling. However, this article does not disclose how to prepare a nitride layer for charge storage. In addition, as disclosed in “Novel 2-bit HfO₂ nanocrystal non-volatile flash memory”, by Yu Hsien Lin, et. al., IEEE Transactions on Electron Devices, v.53, no.4, p.782-788, 2006, HfO₂ nanocrystals can be used as charge trap layer and for 2-bit percell storage. However, this article did not disclose how to form HfO₂ as charge trap layer. Furthermore, neither of the documents has presented a method of forming an SoC by integrating memory circuits and the logic circuits together as described above.

### SUMMARY OF THE INVENTION

An object of the present invention is to provide solutions for integration of semiconductor memory cells capable of high density data storage together with logic transistors. The memory cells and logic transistors are formed and fabricated by the same MOS transistor structure and process flow except that charge trapping sites are selectively formed in the gate dielectric of memory cell (i.e. no trapping sites in the gate dielectric of logic transistors) by adding a simple step of implantation.

To this end, an embodiment of the invention provides a method for fabricating an embedded semiconductor memory device, comprising: preparing a semiconductor substrate comprising region IA and region IB; forming gate dielectric layers and gate structures sequentially on the semiconductor substrate, with the gate dielectric layers in region IA being a charge trap region (for forming memory cells), and the gate dielectric layers in region IB being a non-charge trap region (for forming logic transistors); forming source/drain extension regions in region IA and region IB; and forming source/drain regions in region IA and region IB, wherein upon application of a voltage to the gate structures, the respective source/drain regions may be electrically connected through channels formed in the semiconductor substrate.

Optionally, the formation of the gate dielectric layers may further include: forming a high-k dielectric layer on the semiconductor substrate as the gate dielectric layer, such as HfO₂, Al₂O₃, La₂O₃, HfSiON or HfAlO₂, with charge traps therein; and performing an ion implantation in the gate dielectric layer in region 1B to eliminate the charge traps, thus forming a non-charge trap region in the gate dielectric layer in region 1B and a charge trap region in the gate dielectric layer in region IA.

Optionally, the implanted ions may be fluorine ions or nitrogen ions, the implantation energy may be determined in accordance with thickness of the gate structures and the gate dielectric layers, and the implantation dosage may range from 1.0E+11 to 1.0E+15 cm⁻².

Optionally, the formation of the gate dielectric layers may further include: forming the gate dielectric layers on the semiconductor substrate, said gate dielectric layers are made of silicon oxide, silicon nitride or a combination thereof, performing an ion implantation in the gate dielectric layer in region IA to generate charge traps, thus forming a charge trap region in the gate dielectric layer in region IA and a non-charge trap region in the gate dielectric layer in region IB.

Optionally, the implanted ions may be silicon ions, germanium ions, nitrogen ions or hafnium ions, the implantation dosage may range from 1.0E+11 to 1.0E+13 cm⁻², the implantation energy may be determined in accordance with the implanted ions and thickness of the gate structures, and an implantation angle may range from 0° to 60°.

Optionally, the channel of the embedded semiconductor memory may be an n-type or a p-type, the ions implanted into the source/drain extension region of the n-type channel embedded semiconductor memory device may be arsenic or antimony or phosphorous ions, and the ions implanted into the source/drain extension region of the p-type channel embedded semiconductor memory device may be indium or boron ions.

Another embodiment of the invention provides an embedded semiconductor memory device, comprising: a semiconductor substrate comprising region IA and region IB; gate dielectric layers and gate structures formed sequentially on the semiconductor substrate; source/drain extension regions formed in region IA and region IB; and source/drain regions formed in region IA and region IB, wherein upon application of a voltage to the gate structures, the respective source/drain regions may be electrically connected through conductive channels formed in the semiconductor substrate; the gate dielectric layer in region IA may be a charge trap region (for forming memory cells), and the gate dielectric layer in region IB may be a non-charge trap region (for forming logic transistors).

Optionally, the gate dielectric layers may consist of a high-k dielectric layer such as HfO₂, Al₂O₃, La₂O₃, HfSiON or HfAlO₂, with charge traps therein. The gate dielectric layer in region IB may form a non-charge trap region by an ion implantation to eliminate the charge traps, and the gate dielectric layer in region IA may form a charge trap region.

Optionally, the implanted ions may be fluorine ions or nitrogen ions, the implantation energy may be determined in accordance with thickness of the gate structures and the gate dielectric layers, and the implantation dosage may range from 1.0E+11 to 1.0E+15 cm⁻².

Optionally, the gate dielectric layers may consist of silicon oxide, silicon nitride or a combination thereof The gate dielectric layers in region IA may form a charge trap region by an ion implantation, and the gate dielectric layer in region IB may form a non-charge trap region.

Optionally, the ions may be silicon ions, germanium ions, nitrogen ions or hafnium ions, the implantation dosage may range from 1.0E+11 to 1.0E+13 cm⁻², the implantation energy may be determined in accordance with the implanted ions and thickness of the gate structures, and the implantation angle may range from 0° to 60°.

Optionally, the channel of the embedded semiconductor memory may be an n-type or a p-type, the ions implanted into the source/drain extension region of the n-type channel embedded semiconductor memory device may be arsenic or antimony or phosphorous ions, and the ions implanted into the source/drain extension region of the p-type channel embedded semiconductor memory device may be indium or boron ions.

A still another embodiment of the invention provides a method for fabricating an embedded semiconductor memory device, comprising: preparing a semiconductor substrate comprising region I and region II, said region I being a core circuit region and including region i and region ii, said region II being an IO (Input and Output) circuit region and including region iii and region iv; forming gate dielectric layers and gate structures sequentially in region I and region II, with the gate dielectric layers in region i and/or region iii being a charge trap region (for forming memory cells), and the gate dielectric layers in region ii and/or region iv being a non-charge trap region (for forming logic transistors); forming source/drain extension regions in region I and region II; and forming source/drain regions respectively in region I and region II, wherein upon application of a voltage to the gate structures, the respective source/drain regions may be electrically connected through conductive channels formed in the semiconductor substrate.

Optionally, the formation of the gate dielectric layers may further include: forming a high-k dielectric layer on the semiconductor substrate as the gate dielectric layers, such as HfO₂, Al₂O₃, La₂O₃, HfSiON or HfAlO₂, with charge traps therein; and performing a function implantation and/or a second ion implantation in the gate dielectric layer in region ii and/or region iv to eliminate the charge traps, thus forming a non-charge trap region in region ii and/or region iv and a charge trap region in the gate dielectric layer in region i and/or region iii.

Optionally, ions for the first ion implantation and/or the second ion implantation may be fluorine ions or nitrogen ions, the implantation energy for the first ion implantation and/or the second ion implantation may be determined in accordance with the implanted ions and thickness of the gate structures, and the implantation dosage for the function implantation and/or the second ion implantation may range from 1.0E+11 to 1.0E+15 cm⁻².

Optionally, the formation of the gate dielectric layers may further include: forming the gate dielectric layers comprising silicon oxide, silicon nitride or a combination thereof on the semiconductor substrate; and performing a first ion implantation and/or a second ion implantation in the gate dielectric layer in region i and/or region iii to generate charge traps, thus forming a charge trap region in region i and/or region iii and a non-charge trap region in region ii and/or region iv.

Optionally, ions for the first ion implantation and/or the second ion implantation may be silicon ions, germanium ions, nitrogen ions or hafnium ions, the implantation dosage for the function implantation and/or the second ion implantation may range from 1.0E+11 to 1.0E+13 cm⁻², the implantation energy for the first ion implantation and/or the second ion implantation may be determined in accordance with the implanted ions and thickness of the gate structures, and the implantation angle for the first ion implantation and/or the second ion implantation may range from 0° to 60°.

Optionally, the channel of the embedded semiconductor memory may be an n-type or a p-type, the ions implanted into the source/drain extension region of the n-type channel embedded semiconductor memory device may be arsenic or antimony or phosphorous ions, and the ions implanted into the source/drain extension region of the p-type channel embedded semiconductor memory device may be indium or boron ions.

A further embodiment of the invention provides an embedded semiconductor memory device, comprising: a semiconductor substrate comprising region I and region II, said region I being a core circuit region and including region i and region ii, said region II being an IO (Input and Output) circuit region and including region iii and region iv; the gate dielectric layers and the gate structures formed sequentially on the semiconductor substrate; the source/drain extension regions formed respectively in region I and region II; and the source/drain regions formed respectively in region I and region II, wherein upon application of a voltage to the gate structures, the respective source/drain regions may be connected electrically through conductive channels formed in the semiconductor substrate, and the gate dielectric layer in region i and/or region iii may be a charge trap region (for flash memory cells), and the gate dielectric layer in region ii and/or region iv may be a non-charge trap region (for logic transistors).

Optionally, the gate dielectric layers may consist of a high-k dielectric layer, such as HfO₂, Al₂O₃, La₂O₃, HfSiON or HfAlO₂, with charge traps therein, the gate dielectric layer in region ii and/or region iv may form a non-charge trap region by a first ion implantation and/or a second ion implantation to eliminate the charge traps, and the gate dielectric layer in region i and/or region iii may form a charge trap region.

Optionally, ions for the first ion implantation and/or the second ion implantation may be fluorine ions or nitrogen ions, the implantation energy for the first ion implantation and/or the second ion implantation may be determined in accordance with the implanted ions and thickness of the gate structures, and the implantation dosage for the first ion implantation and/or the second ion implantation may range from 1.0E+11 to 1.0E+15 cm⁻².

Optionally, the gate dielectric layers may consist of silicon oxide, silicon nitride or a combination thereof, the gate dielectric layer in region i and/or region iii may form a charge trap region by a first ion implantation and/or a second ion implantation to eliminate the charge traps, and the gate dielectric layer in region ii and/or region iv may form a non-charge trap region.

Optionally, ions for the first ion implantation and/or the second ion implantation may be silicon ions, germanium ions, nitrogen ions or hafnium ions, the implantation dosage for the first ion implantation and/or the second ion implantation may range from 1.0E+11 to 1.0E+13 cm⁻², an implantation energy for the function implantation and/or the second ion implantation may be determined in accordance with the implanted ions and thickness of the gate structures, and the implantation angle for the first ion implantation and/or the second ion implantation may range from 0° to 60°.

Optionally, the channel of the embedded semiconductor memory may be an n-type or a p-type, the ions implanted into the source/drain extension region of the n-type channel embedded semiconductor memory device may be arsenic or antimony or phosphorous ions, and the ions implanted into the source,drain extension region of the p-type channel embedded semiconductor memory device may be indium or boron ions.

The invention can be advantageous over prior arts in that, in an embodiment of the invention, the gate dielectric layer in region IA is a charge trap region for memory cells, and the gate dielectric layer in region IB is a non-charge trap region for logic transistors by the use of implantation. In this way, not only logic transistors and memory cells are formed together on the same substrate for SoC applications, but also the logic transistors have the same characteristics as those from standard CMOS logic process so that all available logic libraries and IP's based on standard CMOS flow can be readily usable.

In another embodiment of the invention, the gate dielectric layers in region i of region I and/or in region iii of region II as charge traps for forming memory cells, and the gate dielectric layers in region ii of region I and/or in region iv of region II has no charge traps for forming logic transistors. The processes for forming the logic transistors are the same as that of the memory cells except the implantation step to create traps in memory cells region or eliminate traps in logic transistors region. The memory cells can store charges in the gate dielectric locally, thus it is suitable to store two-bit-per-cell and thus capable of high storage capacity. Furthermore, the semiconductor memory device can be fabricated in different circuit regions flexibly as desired (e.g. a core circuit region with a thin gate dielectric layer or an IO circuit region with a thick gate dielectric layer) according to the invention.

In another embodiment of the invention, a high-k dielectric layer, such as HfO₂, Al₂O₃, La₂O₃, HfSiON or HfAlO₂, with charge traps therein, can be used as a gate dielectric layer for forming memory cells with local charge storage capability (i.e. for two-bit-per-cell).

In yet another embodiment of the invention, silicon nitride, silicon oxynitride, silicon oxide or a combination thereof can be used to form a gate dielectric layer, and an ion implantation can be performed on the gate dielectric layer for creating charge traps in it. Then, an MOS transistor with gate dielectric with charge traps performs as memory cell for two-bit-per-cell storage.

### BRIEF DESCRIPTION OF THE DRAWINGS

FIG. 1A to FIG. 1P are schematic diagrams for the fabrication of memory cells and logic transistors according to a first embodiment of the invention;

FIG. 2A to FIG. 2I are schematic diagrams for the fabrication of memory cells and logic transistors according to a second embodiment of the invention;

FIG. 3A to FIG. 3C are schematic diagrams of a structure of a memory cell according to a third embodiment of the invention;

FIG. 4A to FIG. 4D are schematic diagrams of a structure of a memory cell according to a fourth embodiment of the invention;

FIG. 5A to FIG. 5D are schematic diagrams of a structure of a memory cell and a logic transistor according to a fifth embodiment of the invention;

FIG. 6A to FIG. 6D are schematic diagrams of a structure of a memory cell and a logic transistor according to a sixth embodiment of the invention;

FIG. 7A to FIG. 7E are schematic diagrams of programming, erasing and read operations for a memory cell according to an embodiment of the invention; and

FIG. 8A to FIG. 8B are schematic diagrams of an energy band structure of silicon oxide as the gate dielectric layer according to the invention.

### DETAILED DESCRIPTION OF THE EMBODIMENTS

This invention provides methods for integrating semiconductor memory cells with logic transistors, so that memory array and logic circuits are integrated together for wide range of applications, as commonly referred as embedded semiconductor memory technology. The memory cell is simply an MOS transistor with charge traps in gate dielectric layer. The logic transistor is simply an MOS transistor with no charge traps in gate dielectric layer. In one aspect, an embodiment of the invention provides a method for fabricating an embedded semiconductor memory device having a gate dielectric layer made of silicon oxide, silicon nitride or a combination thereof, ions can be implanted selectively into the gate dielectric layer of memory cell region on a semiconductor substrate to form charge traps hence the gate dielectric layer are capable of charge storage, while no ions are implanted into logic transistor region. In this aspect, an embodiment of the invention provides a semiconductor substrate comprising a core circuit region (i.e. region I) and an IO (Input and Output) circuit region (i.e. region A, where ions are implanted selectively into the gate dielectric of core memory cell region of region I (i.e. region i) and the gate dielectric of IO memory cell region of region II (i.e. region iii), and thus both region i and region iii become memory cell regions. Note that the thickness of gate dielectric on core circuit region is thinner than that on IO circuit region due to lower operation voltage requirements, therefore the memory cells formed in region I or region II may operate with different operation voltages. Furthermore, region ii of region I and region iv of region II are logic transistor regions, and thus together with memory cells, both region I and region II can serve as embedded memory circuits with capability of operating at different voltages. Note that the embodiments shall not limit the scope of the invention thereto.

Furthermore, in an embodiment of the invention, an n-type channel MOS transistor can be fabricated as a memory cell. Alternatively, a p-type channel MOS transistor or a CMOS transistor including both n-type and p-type channel MOS transistors can be fabricated as memory cells correspondingly. Note that those embodiments shall not limit the scope of the invention thereto.

In another aspect, an embodiment of the invention provides a method for fabricating an embedded semiconductor memory device and a structure thereof, wherein, for an MOS transistors having a gate dielectric layer consisting of high-k gate dielectric layer, such as HfO₂, Al₂O₃, La₂O₃, HfSiON or HfAlO₂, the high-k gate dielectric layer are capable of charge storage due to charge traps contained therein. In an embodiment of the invention, charge traps can be eliminated through implantation of ions selectively into the high-k gate dielectric layer, thus a region into which no ions are implanted can form memory cells, and a region into which ions are implanted can form logic transistors. In this aspect, an embodiment of the invention provides a semiconductor substrate comprising a core circuit region (i.e. region I) and an IO circuit region (i.e. region A, and ions are implanted selectively into a core logic circuit region in region I (i.e. a region ii) and an IO logic circuit region in region II (i.e. region iv) respectively to form a core logic transistor region and an IO logic transistor region, and thus both region I and region II can serve as embedded memory circuits with capability of operating at different voltages. Furthermore, in an embodiment of the invention, an n-type channel MOS transistor can be fabricated as an n-type memory cell. Alternatively, a p-type channel MOS transistor or a CMOS pair including both n-type and p-type channel MOS transistors can be fabricated as memory cells correspondingly. Note that those embodiments shall not limit the scope of the invention thereto.

First, a method for fabricating an embedded semiconductor memory device according to an embodiment of the invention comprises: preparing a semiconductor substrate comprising region I and region II, said region I being a core circuit region and including region i and region ii, said region II being an IO (Input and Output) circuit region and including region iii and region iv; forming gate dielectric layers and gate structures sequentially in region I and region II of the semiconductor substrate; forming source/drain extension regions in region I and region II of the semiconductor substrate; and forming source/drain regions respectively in region I and region II of the semiconductor substrate, wherein upon application of a voltage to the gate structures, the respective source/drain regions may be electrically connected through conductive channels formed in the semiconductor substrate, the gate dielectric layer(s) in region i and/or region iii is(are) a charge trap region (for forming memory cells), and the gate dielectric layer(s) in region ii and/or region iv is(are) a non-charge trap region (for forming logic transistors).

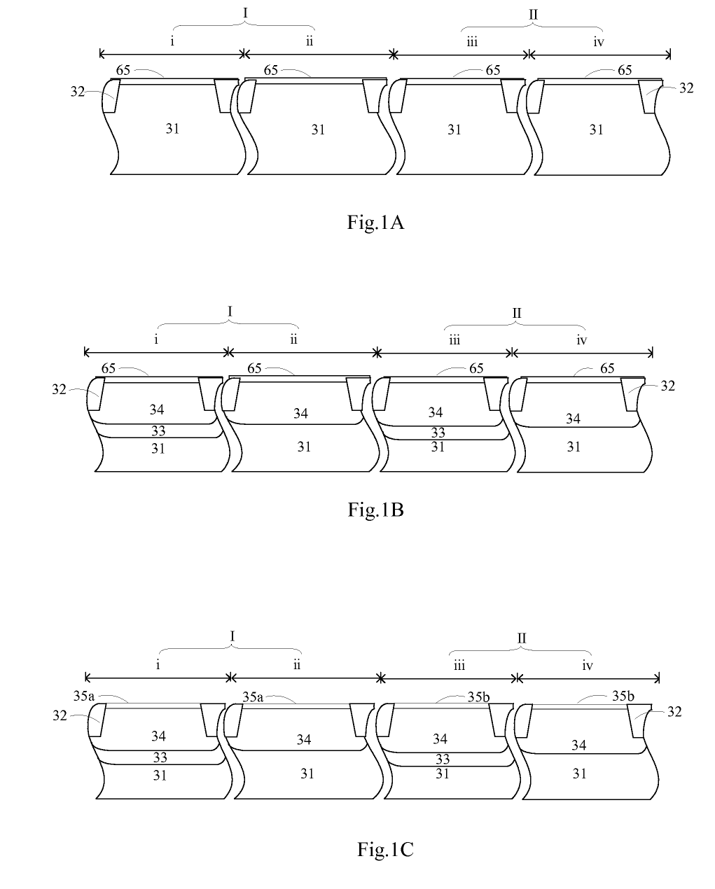

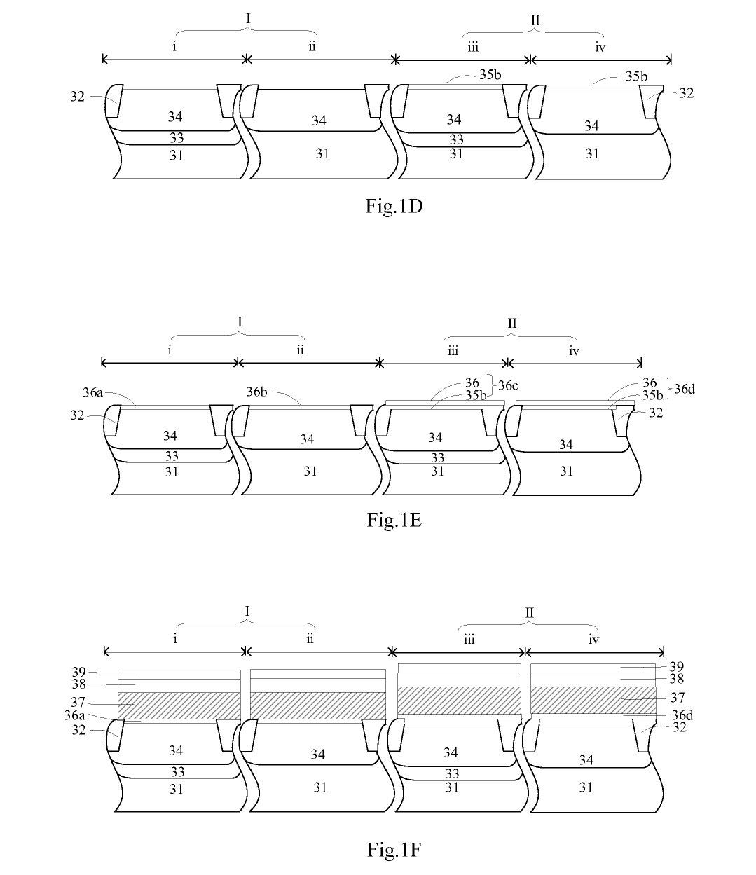

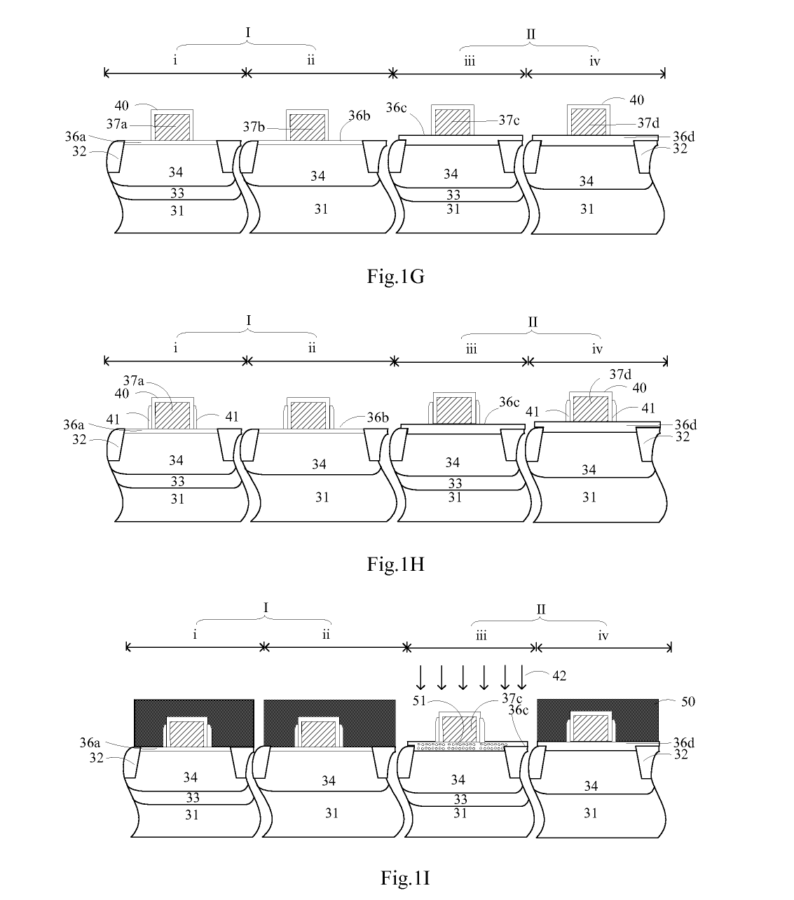

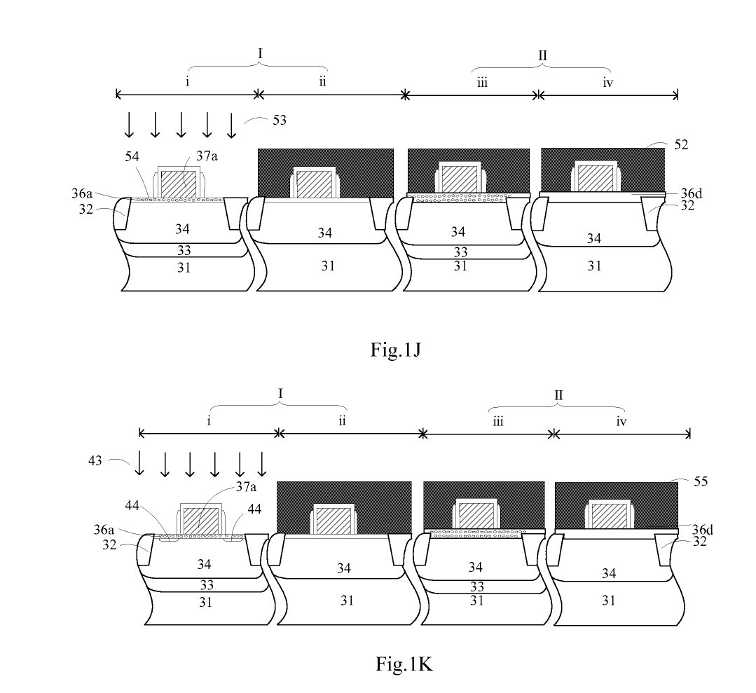

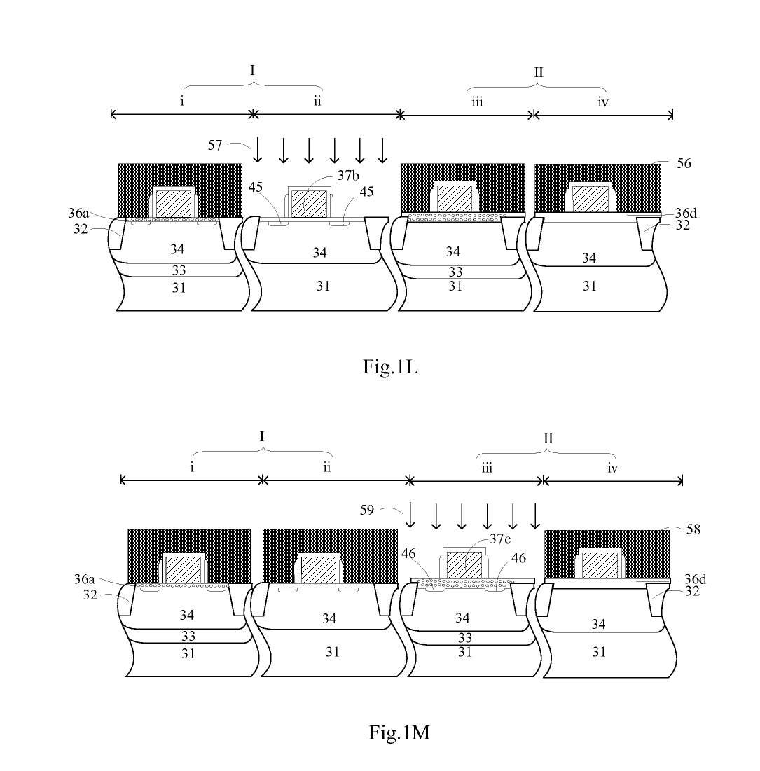

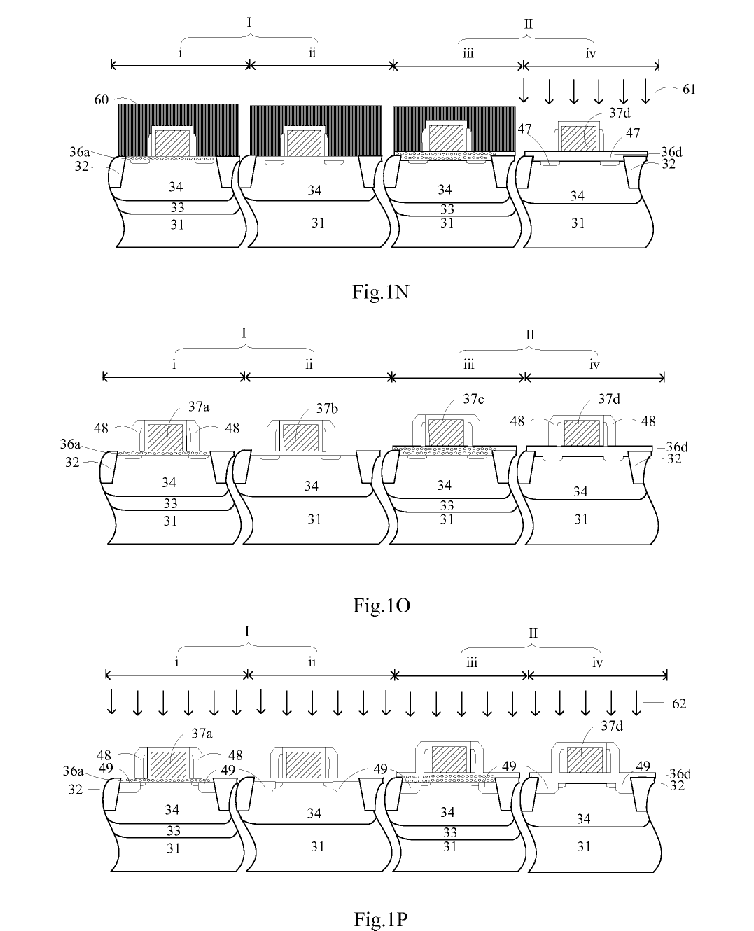

As illustrated in FIGS. 1A to 1P, a method for fabricating n-type memory cells and logic transistors according to a first embodiment of the invention will be described hereinafter according to the first embodiment of the invention, in which a p-type silicon substrate is used as the semiconductor substrate, and a gate structure of an MOS transistor is made of polysilicon. The p-type MOS transistors (for memory cells and logic transistors) can be fabricated similarly, and thus its fabrication methods will not be described for simplicity.

Referring to FIG. 1A, a p-type semiconductor substrate 31 is prepared with shallow trenches isolation structure 32 formed therein, and can be separated into region I and region II according to circuit function. Region I is a core circuit region with thinner gate dielectric for lower operating voltage, and can be further divided into region i (i.e. a core memory cell region) and region ii (i.e. a core logic transistor region), and region II is an IO circuit region with thicker gate dielectric for higher operating voltage, and can be further divided into region iii (i.e. an IO memory cell region) and region iv (i.e. an IO logic transistor region). With the method for fabricating, memory devices can be formed in both region I and region II with different gate dielectric thickness (with implications of shorter charge retention time for cells on region I than region A.

The shallow trench isolation structure 32 can be formed on the semiconductor substrate 31 through any technology well known to those skilled in the art. In a preferable embodiment, firstly, a first oxide layer with thickness of 100 Å is grown on the semiconductor substrate 31; a silicon nitride layer with thickness of 350 Å is formed on the first oxide layer; an active region is defined by photoresist using a photolithograph process; the silicon nitride layer and the first oxide layer are etched, and then the semiconductor substrate is etched by 5000 Å to form a groove; the photoresist is removed; a second silicon oxide layer with thickness of 100 Å is formed on the semiconductor 31; then the groove is filled with silicon oxide with thickness of 5500 Å through high-density plasma chemical vapor deposition; rapid annealing is performed at a temperature of 1000° C. for 20 s to enhance the binding of the high-density plasma silicon oxide with the semiconductor substrate 31; planarization is performed through a chemical mechanical polishing apparatus to finish fabricating the shallow trench isolation structure 32; and a third oxide layer 65 with thickness of 100 Å is formed by thermal oxidation on the semiconductor substrate 31 for protecting the surface of the semiconductor substrate 31 from the damage of subsequent process which is well known to those skilled in the art.

Next, referring to FIG. 1B, deep n-well regions 33 and p-well regions 34 are formed in region i and region iii of the p-type semiconductor substrate 31, and p-well regions 34 are formed in region ii and region iv, the process for forming the n-well regions 33 and p-well regions 34 are well known to those skilled in the art. In a preferable embodiment of the invention, phosphor or arsenic ions are implanted into region i and region iii selectively through a deep n-well region masking step. The implantation energy ranges from 1 to 3 MeV, preferably 1.5 MeV, and the implantation dosage ranges from 1.0E+13 to 1.0E+14 cm⁻², preferably 2.0E+13 cm⁻², thus obtains a deep n-well depth ranging from 400 to 600 nm so as to form the deep n-well region 33. Boron ions are implanted into region i, region ii, region iii and region iv selectively through a p-well masking step with the implantation energy ranging from 400 to 800 KeV, preferably 600 KeV, and the implantation dosage ranging from 1.0E+13 to 6.0E+13 cm⁻², preferably 2.0E+13 cm⁻², thus obtaining a p-well depth ranging from 300 to 500 nm.

After the ions implantation for the deep n-well region and p-well region, a rapid thermal annealing can be performed in order to anneal the damage from implantation, preferably with a temperature of 1050° C. and a duration of 30 s.

Next, referring to FIG. 1C, the third oxide layer 65 is removed from the surface of the semiconductor substrate 31, and then a first dielectric layer 35a is formed in region I and a first dielectric layer 35b is formed in region II. The first dielectric layers 35a and 35b is of same thickness and can be made of silicon oxide, silicon oxynitride, silicon nitride or a combination thereof Preferably, in an embodiment of the invention, the first dielectric layers 35a and 35b is silicon oxide by thermal oxidization process. Thickness of the first dielectric layers 35a and 35b are determined as needed, 32A.

Referring to FIG. 1D, the first dielectric layer 35a in region I is removed selectively while the first dielectric layer 35b in region II remains by photoresist masking process and followed by wet HF dip and photoresist removal.

Referring to FIG. 1E, a second dielectric layer 36 is formed on the p-well regions 34 in region I and on the first dielectric layer 35b in region II. The second dielectric layer 36 in region i and ii are referred to as 36a and 36b respectively for convenience. The first dielectric layer 35b and the second dielectric layer 36 result in a final thickness in region iii and region iv and are referred to as 36c and 36d respectively. The second dielectric layers 36 can be made of silicon oxide, silicon oxynitride, silicon nitride or a combination thereof Preferably, in an embodiment of the invention, the second dielectric layers 36 can be silicon oxide by thermal oxidization process. Thickness of the second dielectric layers 36 is determined as needed, preferably 23A. The thickness of 36a and 36b is 23 Å for 1.2 v operating voltage, and the final thickness of 36c and 36d is 40 Å for 1.8 v operating voltage. The thickness of the first dielectric layer 35b and second dielectric layer 36 can certainly be adjusted for various operating voltage for core circuit, such as 1.0 v, 1.5 v, 1.8 v, 2.5 v, and IO circuits, such as 1.8 v, 2.5 v, 3.3 v, or 5 v.

Referring to FIG. 1F, in an embodiment of the invention, a polysilicon layer 37 with thickness ranging from 700 to 1500 Å, preferably 1250 Å, is formed on the gate dielectric layers 36a and 36b in region I and the gate dielectric layers 36c and 36d in region II by a chemical vapor deposition process.

Next, the polysilicon layer 37 is doped by implantation of phosphor ions. The energy for the doping ranges from 10 to 200 KeV and the dosage of the doping ranges from 1.0E+14 to 1.0E+16 cm⁻².

Next, a silicon oxynitride layer 38 is formed on the polysilicon layer 37 as a hard mask for etching the polysilicon layer 37 in later process, preferably having a thickness of 200 to 300 Å and through a chemical vapor deposition process.

Next a second silicon oxide layer 39 is formed on the silicon oxynitride layer 38 also as a hard mask for etching the polysilicon layer 37 in later process, preferably with thickness of 50 to 100 Å and through a chemical vapor deposition process.

Referring to FIG. 1G, a photoresist masking step is performed and the second silicon oxide layer 39 and the silicon oxynitride layer 38 are etched using the photoresist as a mask and then the photoresist is removed. Next, the polysilicon layer 37 is etched using the second silicon oxide layer 39 and the silicon oxynitride layer 38 as hard masks until the gate dielectric layers 36a and 36b in region I and the gate dielectric layers 36c and 36d in region II are exposed. The gate structures 37a, 37b, 37c and 37d are therefore formed in region i, region ii, region iii and region iv respectively as in FIG. 1G

Next, the second silicon oxide layer 39 and the silicon oxynitride layer 38 remaining on the gate structures 37a, 37b, 37c and 37d are removed, preferably by a wet etching process using hydrofluoric acid solution and hot phosphoric acid solution sequentially.

Next, the gate structures 37a, 37b, 37c and 37d are oxidized at a temperature of 800° C. to form a third silicon oxide layer 40 with thickness ranging from 10 to 20 Å for the purpose of protecting the gate dielectric layers at edges of the polysilicon gate structures 37a, 37b, 37c and 37d.

Referring to FIG. 1H, a first sidewall spacer 41 is formed at both sides of the gate structures 37a, 37b, 37c and 37d for the purpose of preventing lateral diffusion between source/drain extension regions of transistors formed in a subsequent process. In particular, the process for forming a first side wall 41 includes: depositing a silicon nitride layer with thickness ranging from 50 to 150 Å on the gate dielectric layers 36a, 36b, 36c and 36d and on the gate structures 37a, 37b, 37c and 37d, and then etching the silicon nitride layer to form the first sidewall spacer 41.

FIG. 1I and FIG. 1J illustrate a process for forming charge traps 51 and charge traps 54 in the gate dielectric layers 36c and 36a respectively. Firstly referring to FIG. 1I, a photoresist mask 50 is formed for opening region iii in region II. Then an ion implantation 42 is performed in region iii, in which the implanted ions are nitrogen, silicon, germanium or hafnium. The implantation energy and the implantation angle can be determined in accordance with the implanted ions and the height of the gate structures, and the implantation dosage ranges from 1.0E+11 to 1.0E+15 cm⁻². Thereafter, there are high-density Si clusters, Ge clusters, Si—Si bonding or Ge—Ge bonding, and hafnium dioxide clusters or the like are formed in the gate dielectric layer 36c and served as electron or hole traps 51 in the gate dielectric layer 36c. Then the photoresist mask 50 is removed.

The implantation angle in the ion implantation 42 is 0° as illustrated in FIG. 1l. Alternatively, a large implantation angle such as 30° to 60° can be applicable, also the semiconductor substrate can be rotated for multi-step implantations, so that the charge traps 51 resulted from the implanted ions may only locate in the gate dielectric 36c near the edge of the gate structure 37c, and the resulted memory cell are capable of charge storage near either the drain side or the source side (i.e. 2 bits per cell). Hereinafter, the implantation angle of any ion implantation for forming charge traps can range from 0° to 60°. However, only an implantation angle of 0° is illustrated for brevity throughout the drawings unless stated otherwise.

In an embodiment of the invention, ion implantations for forming charge traps in gate dielectric layer may be performed after forming a gate structure (as illustrated in FIG. 1I or after forming a gate dielectric layer (not illustrated here). Then, after the photoresist mask is removed, the gate structure is formed on gate dielectric layer and the rest of process steps is continued. Note that the embodiments shall not limit the scope of the invention thereto.

In a preferable embodiment of the invention, nitrogen ions are implanted during the ion implantation 42 with the implantation energy ranging from 50 to 200 KeV, preferably 150 KeV, and the implantation dosage ranging from 1.0E+11 to 1.0E+15 cm⁻², preferably 2.0E+12 cm⁻². The height of the gate structure 37c and the thickness of gate dielectric layer 36c are 1250 Å and 55 Å. As a result, there are charge traps 51 formed with a density of larger than 1.0E+10 cm⁻² in the gate dielectric layer 36c.

In an alternative embodiment of the invention, silicon ions are implanted for the ion implantation 42. The implantation energy ranges from 200 to 800 KeV, preferably 550 KeV and the implantation dosage ranges from 1.0E+11 to 1.0E+15 cm⁻², preferably 5E+12 cm⁻². The height of the gate structure 37c and the thickness of the gate dielectric layer 36c are 1250Å and 55 Å respectively. As a result, there are charge traps 51 formed with a density of larger than 1.0E+10 cm⁻² in the gate dielectric layer 36c.

In an alternative preferable embodiment of the invention, germanium ions are implanted during the ion implantation 42. The implantation energy ranges from 200 to 800 KeV, preferably 600 KeV, and the implantation dosage ranges from 1.0E+11 to 1.0E+15 cm⁻², preferably 2.0E+12 cm⁻². The height of the gate structure 37c and the thickness of the gate dielectric layer 36c are 1250 Å and 55 Å respectively. As a result, there are charge traps 51 formed with a density of larger than 1.0E+10 cm⁻² in the gate dielectric layer 36c.

In another preferable embodiment of the invention, hafnium ions are implanted during the ion implantation 42 with the implantation energy ranging from 200 to 800 KeV, preferably 700 KeV, and the implantation dosage ranging from 1.0E+11 to 1.0E+15 cm⁻², preferably 8E+12 cm⁻². The height of the gate structure 37c and the thickness of the gate dielectric layer 36c are 1250 Å and 55 Å respectively. As a result, there are charge traps 51 formed with a density of larger than 1.0E+10 cm⁻² in the gate dielectric layer 36c.

Next, referring to FIG. 1J, the charge traps 54 are formed in the gate dielectric layer 36a through the following steps: a photoresist mask 52 is formed for opening region i of region I. Then an ion implantation 53 is performed in region i, in which the implanted ions are nitrogen, silicon, germanium or hafnium. The implantation energy and the implantation angle can be determined in accordance with the implanted ions and the height of the gate structures, and the implantation dosage ranges from 1.0E+11 to 1.0E+15 cm⁻². Thereafter, there are high-density Si clusters, Ge clusters, Si—Si bonding or Ge—Ge bonding, and hafnium dioxide clusters or the like are formed in the gate dielectric layer 36a and serve as electron or hole traps 54 in the gate dielectric layer 36a. Then the photoresist layer 52 is removed.

In an alternative embodiment of the invention, silicon ions are implanted during the second ion implantation 53. The implantation energy ranges from 200 to 800 KeV, preferably 550 KeV, and the implantation dosage ranges from 1.0E+11 to 1.0E+15 cm⁻², preferably 5.0E+12 cm⁻². The gate structure 37c and the gate dielectric layer 36c are 1250 Å and 55 Å in thickness respectively. As a result, there are charge traps 51 formed with a density of larger than 1.0E+10 cm⁻² in the gate dielectric layer 36a.

In another preferably embodiment of the invention, hafnium ions are implanted during the second ion implantation 53 with the implantation energy ranging from 200 to 800 KeV, preferably 700 KeV, and the implantation dosage ranging from 1.0E+11 to 1.0E+15 cm⁻², preferably 8.0E+12 cm⁻². The gate structure 37c and the gate dielectric layer 36c are 1250 Å and 55 Å in thickness respectively. As a result, there are charge traps 51 formed with a density of larger than 1.0E+10 cm⁻² in the gate dielectric layer 36a.

Referring to FIG. 1K, n-type source/drain extension regions 44 is formed at each side of the gate structure 37a in region i (for memory cells) through the following steps: a photoresist mask 55 opens region i. Then ion implantation 43 is performed in region i, where implanted ions are arsenic or antimony or phosphorous. In this case, a PN junction forms between n-type source/drain extension regions 44 and the p-well region 34 and the PN junction can be relatively shallow and narrow. During programming operation of memory cell, the internal electrical field near the PN junction can be enhanced, thus facilitating the tunneling of hot carriers through the narrow PN junction to enter the gate dielectric layer 36a below the gate structure 37a. Then the photoresist mask 55 is removed. Note that the implantation angle of 0° will be applied to all ion implantations for forming source/drain extension regions.

In an alternative embodiment of the invention, arsenic ions are implanted into the semiconductor substrate 31 by the ion implantation 43 for n-type source/drain extension regions 44. The implantation energy ranges from 5 to 50 KeV and the implantation dosage ranges from 1.0E+12 to 1.0E+15 cm⁻². As a result, the depth of the n-type source/drain extension regions 44 formed in the semiconductor substrate 31 is less than 200 nm.

Referring to FIG. 1L, n-type source/drain extension regions 45 is formed at each side of the gate structure 37b in region ii (for logic transistors) through the following steps: a photoresist mask 56 is formed for opening region ii. Then ion implantation 57 is performed, where the implanted ions are phosphorous, arsenic, antimony or a combination thereof. Then the photoresist mask 56 is removed.

In an alternative embodiment of the invention, phosphorous ions are implanted into the semiconductor substrate 31 by the ion implantation 57 for forming n-type source/drain extension regions 45 in region ii with the implantation energy ranging from 5 to 50 KeV and the implantation dosage ranging from 1.0E+11 to 1.0E+14 cm⁻². As a result, the depth of n-type source/drain extension regions 45 is less than 200 nm.

Referring to FIG. 1M, n-type source/drain extension regions 46 is formed at each side of the gate structure 37c in region iii (for memory cells) through the following steps: a photoresist mask 58 is formed for opening region iii. Then an ion implantation 59 is performed, where the ions implanted are arsenic or antimony or phosphorous. In this case, a PN junction formed between n-type source/drain extension regions 46 and the p-well region 34 can be relatively shallow and narrow. During programming operation of the memory cell, an internal electrical field nearby the PN junction can be enhanced, thus facilitating the tunneling of hot carriers through the narrow PN junction to enter the gate dielectric layer 36c below the gate structure 37c. At last, the photoresist layer 58 is removed.

In an alternative embodiment of the invention, arsenic ions are implanted into the semiconductor substrate 31 during the ion implantation 59 for forming the n-type source/drain extension regions 46. The implantation energy ranges from 5 to 50 KeV and the implantation dosage ranges from 1.0E+12 to 1.0E+15 cm⁻². As a result, the depth of the third source/drain extension region 46 formed in the semiconductor substrate 31 is less than 200 nm after the implantation 59.

Referring to FIG. 1N, n-type source/drain extension regions 47 is formed at each side of the gate structure 37d in region iv (for logic transistors) through the following steps: a photoresist mask 60 is formed for opening region iv. Then ion implantation 61 is performed, where the implanted ions are phosphorous, arsenic, antimony or a combination thereof Then the photoresist mask 60 is removed.

In an alternative embodiment of the invention, phosphor ions are implanted into the semiconductor substrate 31 during the ion implantation 61 for forming n-type source/drain extension regions 47. The implantation energy ranges from 5 to 50 KeV and the implantation dosage ranges from 1.0E+11 to 1.0E+14 cm⁻². As a result, the depth of n-type source/drain extension regions 47 is less than 200 nm.

n-type source/drain extension region 44 and 46 are for memory cells (with thin and thicker gate dielectric respectively); and for simplicity they may be formed together by using same masking step and same implantation dose and energy (i.e. photoresist mask 55 and 58 merged together for opening both region i and iii simultaneously, and then perform implantation either 59 or 43). Certainly, the source/drain extension junction 44 and 46 can be best optimized by using separate masking steps and separate implantation (as illustrated in FIG. 1K and FIG. 1M) for memory cell with thin and thicker gate dielectric respectively. Similarly, the n-type source/drain extension regions 45 and 47 are for logic transistors (with thin and thicker gate dielectric respectively), and for simplicity, they may be formed in the same masking step and using same implantation dose and energy in similar manner. Furthermore, the sequence of process illustrated in FIG. 1K, 1L, 1M, and 1N can be interchangeable. Correspondingly, as not shown in this illustration, the p-type source/drain extension regions for memory cells and logic transistors can be formed similarly except by using p-type implantation ions.

Referring to FIG. 1O, a second sidewall spacer 48 is formed on the first sidewall spacer 41 at each side of the gate structures 37a, 37b, 37c and 37d for compensating the lateral diffusion between the heavily doped source/drain regions of transistors formed during subsequent process. In an alternative embodiment of the invention, a silicon oxide layer and silicon nitride layer are sequentially deposited on the semiconductor substrate 31 by using CVD method. The thicknesses of the silicon oxide layer and the silicon nitride layer are 200 Å and 700 Å respectively. Then a blank plasma etching of silicon nitride layer and silicon oxide layer are sequentially performed to form the second sidewall spacer 48.

Referring to FIG. 1P, an ion implantation 62 for forming the n-type source/drain regions 49 is performed selectively in region I and region II and at each side of the gate structures 37a, 37b, 37c and 37d using masking step (photo-resist mask is not shown here). The ions implanted during the ion implantation 62 for forming the source/drain regions 49 are n-type ions, preferably phosphor ions, arsenic ions or a combination thereof. The implantation energy ranges from 20 to 200 KeV, and the implantation dosage ranges from 1.0E+14 to 1.0E+16 cm⁻². Thus, the source/drain regions 49 of n-type MOS transistors are formed after the ion implantation 62. Note that the implantation angle in the ion implantation 62 for forming the source/drain regions 49 is 0°. Note that, as not shown in this illustration, the p-type source/drain regions for memory cells and logic transistors can be formed similarly by using p-type implantation ions.

As illustrated in FIGS. 1A to 1P, charge traps can be formed in a gate dielectric layer in core circuit region (i.e. region i of region I). Due to the thinner gate dielectric layers 36a and 36b in region I than in region II, a memory cell formed in region I has shorter charge retention time and can perform similar to a dynamic random access memory (DRAM) cell. Similarly, charge traps can be formed in a gate dielectric layer in IO circuit region, i.e. region iii of region II. Thus, the memory cell formed with thicker gate dielectric in region iv can perform as a nonvolatile memory.

With the processes implemented as above, a resultant embedded semiconductor memory device can be illustrated in FIG. 1P. The embedded semiconductor memory device includes: a semiconductor substrate 31 comprising region I and region II, said region I being a core circuit region and including region i and region ii, said region II being an IO (Input and Output) circuit region and including region iii and region iv; the gate dielectric layers and the gate structures formed sequentially on the semiconductor substrate 31; source/drain extension regions 47 formed respectively in region I and region II of the semiconductor substrate 31; and source/drain regions 49 formed respectively in region I and region II, wherein upon application of a voltage to the gate structures, the respective source/drain regions 49 may be connected electrically through conductive channels formed in the semiconductor substrate 31, and the gate dielectric layer 36a in region i and the gate dielectric layer 36c in region iii may be charge trap regions (for memory cells), and the gate dielectric layer 36b in region ii and the gate dielectric layer 36d in region iv may be non-charge trap regions (for logic transistors).

In an embodiment of the invention, both n-type and p-type memory cells and logic transistors can be formed in core circuit region and/or IO circuit region, thus a complete embedded memory circuits (i.e. memory and logic circuits) can be formed together entirely with thinner gate dielectric (in core region) or entirely with thicker gate dielectric (in IO region) or a combination of these. The embedded memory circuit with thinner gate dielectric can be operated with lower voltage, and similarly thicker gate dielectric for higher operating voltage. The embodiments shall not limit the invention thereto.

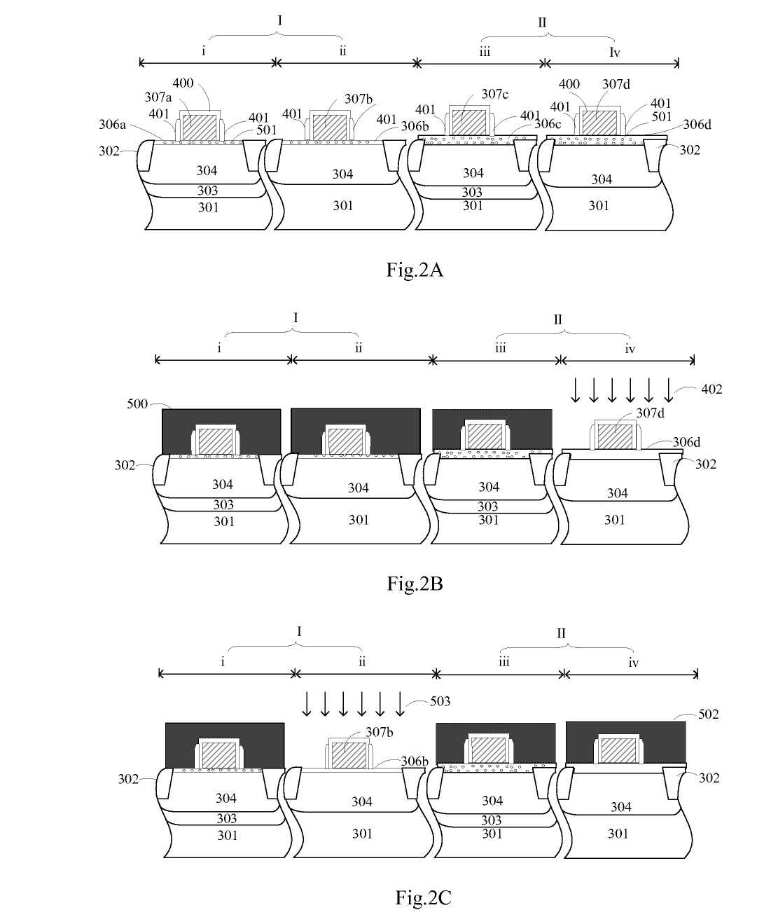

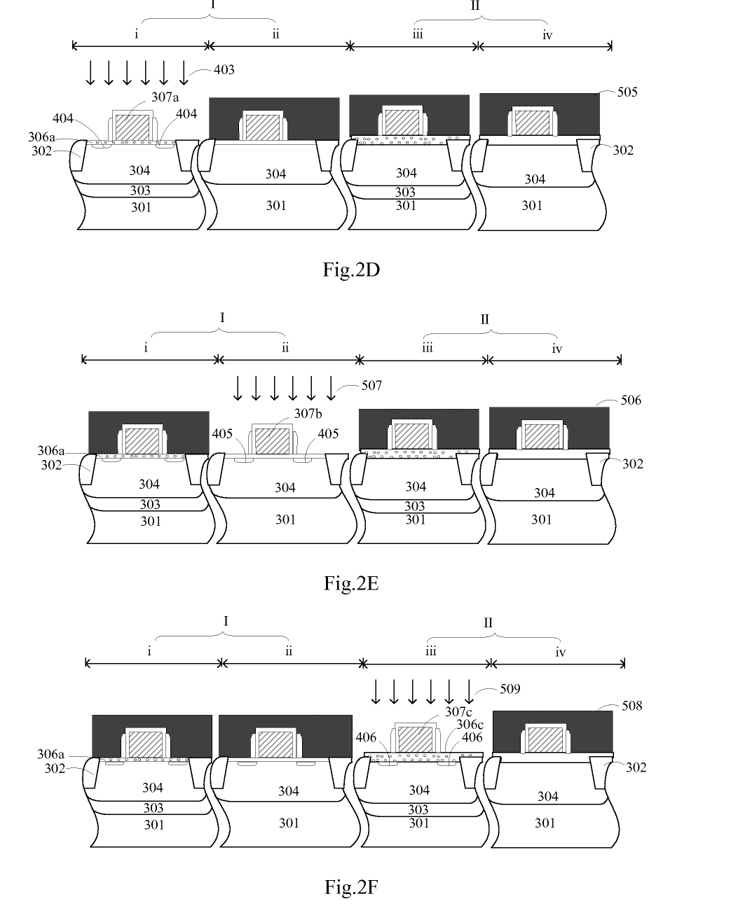

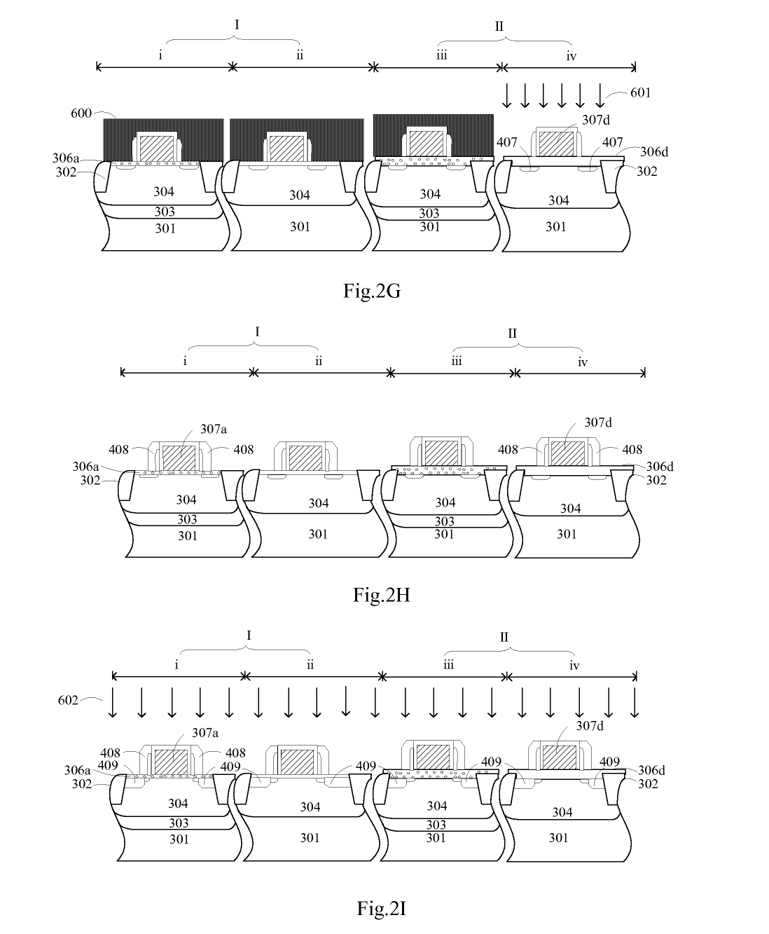

The method of fabrication of memory cells and logic transistors according to a second embodiment of the invention is illustrated in FIGS. 2A to 2I. Referring to FIG. 2A, the semiconductor substrate 301 can be functionally divided into region I and II. Region I is a core circuit region (with thinner gate dielectric 306a and 306b) and further divided into region i, a core memory cell region, and region ii, a core logic transistor region. Region II is an IO circuit region (with thicker gate dielectric 306c and 306d) and further divided into region iii, an IO memory cell region, and region iv, an IO logic transistor region.

In the semiconductor substrate 301, shallow trenches 302, deep n-well regions 303 and p-well regions 304 are formed; gate dielectric layers 306a and 306b are formed in region I; gate dielectric layers 306c and 306d are formed in region II; gate structures 307a, 307b, 307c and 307d are formed respectively on the gate dielectric layers 306a and 306b in region I and the gate dielectric layers 306c and 306d in region II; and a first sidewall 401 is formed at each side of the gate structures 307a, 307b, 307c and 307d. Such a structure can be formed with reference to FIG. 1A to FIG. 1H in connection with the first embodiment.

The gate dielectric layers 306a, 306b, 306c and 306d are made of a high-k dielectric material, such as HfO₂, Al₂O₃, La₂O₃, HfSiON or HfAlO₂. Charge traps 501 are contained in the high-k dielectric layer, and are formed in the deposition process for the high-k dielectric layer. The charge traps 501 in the gate dielectric layers 306a, 306b, 306c and 306d can capture charges and just serves for memory cell to store charges. However, the existence of the charge traps 501 in logic transistor is not desirable due to the unstable threshold voltage, and hence a method for eliminating charge traps in high-k is essential for logic transistors.

FIG. 2B and FIG. 2C illustrate a process for eliminating charge traps 501 in the gate dielectric layers 306d and 306b as described below. Firstly, referring to FIG. 2B, a photoresist mask 500 is formed for opening region iv in region II. Then an first ion implantation 402 is performed with fluorine ions or nitrogen ions, where the energy for the first ion implantation 402 is determined in accordance with the implanted ions and height of the gate structure 37d, and the dosage ranges from 1.0E+11 to 1.0E+15 cm⁻². The charge traps 501 in the gate dielectric layer 306d can be eliminated effectively after the first implantation 402 and annealing in subsequent process steps, thus forming a non-charge trap region for logic transistors. Since the gate dielectric layer 306c in region iii remaining has charge traps and is just suitable for memory cells. Then the photoresist layer 500 is removed.

In an alternative embodiment of the invention, fluorine ions are implanted during the first ion implantation 402. The implantation energy ranges from 50 to 200 KeV and the dosage ranges from 1.0E+11 to 1.0E+15 cm⁻². The implantation angle of all ion implantations for eliminating charge traps is 0° and thus it is possible to eliminate charge traps in gate dielectric layers underneath the gate structure. Since the height of the gate structure 307d and the thickness of the gate dielectric layer 306d in region iv are 1250 Å and 55 Å respectively, fluorine ions are preferably implanted with an energy of 150 KeV and an dosage of 3.0E+14 cm⁻². The charge traps 501 in the gate dielectric layer 306d are reduced or eliminated after the first ion implantation 402 and subsequent annealing process.

In another preferable embodiment of the invention, nitrogen ions are implanted during the first ion implantation 402. The implantation energy ranges from 50 to 200 KeV and the implantation dosage ranges from 1.0E+11 to 1.0E+15 cm⁻². In accordance of the height of the gate structure 307d (1250 Å) and the thickness of the gate dielectric layer 306d (55 Å) in region iv, nitrogen ions are preferably implanted with an implantation energy of 100 KeV and the implantation dosage of 2.0E+14 cm⁻². The charge traps 501 in the gate dielectric layer 306d are reduced or eliminated after the first ion implantation 402 and subsequent annealing in process.

Next, referring to FIG. 2C, a process for eliminating the charge traps 501 in the gate dielectric layer 306b underneath the gate structure 307b in region ii of region I includes the following steps: a photoresist mask 502 is formed for opening region ii in region I. Then an second ion implantation 503 is performed, where the implanted ions are nitrogen ions or fluorine ions, the implantation energy is determined in accordance with the implanted ions and the height of the gate structures 307b, and the implantation dosage ranges from 1.0E+11 to 1.0E+15 cm⁻². The charge traps 501 in the gate dielectric layer 306b in region ii are eliminated effectively after the second ion implantation 503 and subsequent annealing in process for logic transistors, and it is possible to restrain instability of a threshold voltage due to the existence of the charge traps 501 in the gate dielectric layer 306b, and region i is still a charge trap region for memory cells. Then the photoresist mask 502 is removed.

In a preferable embodiment of the invention, fluorine ions are implanted during the second ion implantation 503. The implantation energy ranges from 50 to 200 KeV and the implantation dosage ranges from 1.0E+11 to 1.0E+15 cm⁻². Since the gate structure 307b and the gate dielectric layer 306b are 1250 Å and 23 Å in thickness respectively, fluorine ions are implanted with an implantation energy 150 KeV and an implantation dosage 5.0E+14 cm⁻². The charge traps 501 in the gate dielectric layer 306b underneath the gate structure 307b are reduced or even eliminated after the second ion implantation 503.

In another preferable embodiment of the invention, nitrogen ions are implanted during the second ion implantation 503. The implantation energy ranges from 50 to 200 KeV and the implantation dosage ranges from 1.0E+11 to 1.0E+15 cm⁻². Since the gate structure 307b and the gate dielectric layer 306b in region ii are 1250 Å and 23 Å in thickness respectively, nitrogen ions are implanted with energy of 130 KeV and dosage of 3.0E+13 cm⁻². The charge traps 501 in the gate dielectric layer 306b underneath the gate structure 307b are reduced or even eliminated after the second ion implantation 503.

For simplicity, implant 402 and 503 may be performed together by using same masking step (i.e. photoresist mask 500 and 502 merged together for opening both region iv and ii simultaneously) and same implant dose and energy for fluorine and nitrogen ions or both in combination. Certainly, if so prefer, the region iv and region ii can be separately optimized for eliminating charge traps in gate dielectric by using separate masking steps and different combination of species, energy, and doses for implantation (as illustrated in FIGS. 2B and 2C).

Referring to FIG. 2D, first n-type source/drain extension regions 404 is formed at each side of the gate structure 307a in region i of the semiconductor substrate 301 through the following steps: a third photoresist layer 505 is formed in region I and region II of the semiconductor substrate 301; the shape of region i is defined using an existing photolithograph technology; and an ion implantation 403 for forming the first source/drain extension region is performed in region i, where the implanted ions are arsenic ions or antimony ions which are difficult to diffuse in the semiconductor substrate 31 due to a large size, and the arsenic ions or antimony ions can not have a large diffusion length even after annealing. In this case, a PN junction formed between first source/drain extension regions 404 and the p-well region 304 of the semiconductor substrate 301 can be relatively shallow and narrow. During programming operation, an internal electrical field nearby the PN junction can be enhanced, thus facilitating tunneling of hot carriers through the narrow PN junction to enter the gate dielectric layer 306a below the gate structure 307a. And finally the third photoresist layer 505 is removed.

In an alternative embodiment of the invention, arsenic ions or antimony ions are implanted into the semiconductor substrate 301 during the ion implantation 403 for forming the first source/drain extension region. The implantation energy ranges from 5 to 50 KeV and the implantation dosage ranges from 1.0E+12 to 1.0E+15 cm⁻². Thereafter, the first source/drain extension regions 404 is formed with depth equal to or less than 200 nm.

Referring to FIG. 2E, second n-type source/drain extension regions 405 is formed at each side of the gate structure 307b in region ii of the semiconductor substrate 301 through the following steps: a fourth photoresist layer 506 is formed in region I and region II of the semiconductor substrate 301; the shape of region ii is defined using an existing photolithograph technology; and an ion implantation 507 for forming the second source/drain extension region is performed in region ii, where the implanted ions are phosphor ions, arsenic ions, antimony ions or a combination thereof. The second source/drain extension region 405 is formed at each side of the gate structure 307b on the p-well region 304 in region ii of the semiconductor substrate 301. And finally the fourth photoresist layer 506 is removed.

In an alternative embodiment of the invention, phosphor ions are implanted into the semiconductor substrate 301 during the ion implantation 507 for forming the second source/drain extension region. The implantation energy ranges from 5 to 50 KeV and the implantation dosage ranges from 1.0E+11 to 1.0E+14 cm⁻². Thereafter, the second source/drain extension regions 405 are formed with depth equal to or less than 200 nm.

Referring to FIG. 2F, third n-type source/drain extension regions 406 is formed at each side of the gate structure 307c in region iii of the semiconductor substrate 301 through the following steps: a fifth photoresist layer 508 is formed in region I and II of the semiconductor substrate 31 firstly; the shape of region iii is defined using an existing photolithograph technology; and an ion implantation 509 for forming the third source/drain extension region is performed in region iii, where the implanted ions are arsenic ions or antimony ions that are difficult to diffuse in the semiconductor substrate 301 due to a large size, and the arsenic ions or antimony ions can not have a large diffusion length even after annealing. In this case, a PN junction formed between the third source/drain extension region 406 and the p-well region 304 of the semiconductor substrate 301 can be relatively shallow and narrow, thus form a sharp junction. During programming operation, an internal electrical field near the PN junction can be enhanced, thus facilitating tunneling of hot carriers through the narrow PN junction to enter the gate dielectric layer 306c below the gate structure 307c.

In an alternative embodiment of the invention, arsenic ions are implanted into the semiconductor substrate 301 during the ion implantation 509 for forming the third source/drain extension region. The implantation energy ranges from 5 to 50 KeV and the implantation dosage ranges from 1.0E+12 to 1.0E+15 cm⁻². The third source/drain extension regions 406 formed in the semiconductor substrate 301 are equal to or less than 200 nm in thickness accordingly.

Referring to FIG. 2Q fourth n-type source/drain extension regions 407 is formed at each side of the gate structure 307d in region iv of the semiconductor substrate 301 through the following steps: a sixth photo-resist 600 is formed in region I and II of the semiconductor substrate 301; region iv is defined using an existing photolithograph technology; and an ion implantation 601 for the fourth source/drain extension regions is performed in region iv, where the implanted ions are phosphor ions, arsenic ions, antimony ions or a combination thereof The fourth source/drain extension regions 407 is formed at each side of the gate structure 307d in the p-well region 304 in region iv of the semiconductor substrate 301 after the implantation.

In an alternative embodiment of the invention, phosphor ions are implanted into the substrate 301 during the ion implantation 601 for the fourth source/drain extension regions with an implantation energy ranging from 5 to 50 KeV and dosage ranging from 1.0E+11 to 1.0E+14 cm⁻². Thereafter, the fourth source/drain extension regions 405 are formed with depth equal to or less than 200 nm.

The n-type source/drain extension regions 404 and 406 are for memory cells (with thin and thicker gate dielectric respectively); and for simplicity they may be formed together by using same masking step and same implantation dose and energy (i.e. photo-resist mask 505 and 508 merged together for opening both region i and iii simultaneously, and then perform implantation either 509 or 403). Certainly, the source/drain extension regions 404 and 406 can be best optimized by using separate masking steps and separate implant (as illustrated in FIG. 2D and FIG. 2F) for memory cell with thin and thicker gate dielectric respectively. Similarly, the n-type source/drain extension regions 405 and 407 are for logic transistors (with thin and thicker gate dielectric respectively), and for simplicity they may be formed at the same masking step with same implant dose and energy in similar manner. Furthermore, the sequence of process illustrated in FIGS. 2D, 2E, 2F, and 2G can be interchangeable. Correspondingly, as not shown in this illustration, the p-type source/drain extension regions for memory cells and logic transistors can be formed similarly except by using p-type implantation ions.

Referring to FIG. 2H, a second sidewall spacer 408 is formed along the first sidewall pacer 401 at each side of the gate structures 307a, 307b, 307c and 307d as the same as illustrated in FIG. 10 for the purpose of preventing lateral diffusion between the source/drain regions of transistors formed during a subsequent process. In a preferable embodiment of the invention, a fourth silicon oxide layer is formed on the semiconductor substrate, then a second silicon nitride layer is formed, and next, a second silicon oxynitride layer is formed for lowering local stress and the amount of defects in sidewall. Thickness of the fourth silicon oxide layer, the second silicon nitride layer and the second silicon oxynitride layer are 150 Å, 200 Å and 700 Å, respectively. Thereafter, the second silicon oxynitride layer, the second silicon nitride layer and the fourth silicon oxide layer are sequentially etched to form the second sidewall 408.

Referring to FIG. 21, an ion implantation 602 for forming the n-type source/drain regions 409 is performed selectively in region I and region II and at each side of the gate structures 307a, 307b, 307c and 307d using masking step (photo-resist mask is not shown here). The ions implanted during the ion implantation 602 for forming the source/drain regions 409 are n-type ions, preferably phosphor ions, arsenic ions or a combination thereof The implantation energy ranges from 20 to 200 KeV, and the implantation dosage ranges from 1.0E+14 to 1.0E+16 cm⁻². Thus, the source/drain regions 409 of n-type MOS transistors are formed after the ion implantation 602. Note that the implantation angle in the ion implantation 602 for forming the source/drain regions 409 is 0°. Note that, as not shown in this illustration, the p-type source/drain regions for memory cells and logic transistors can be formed similarly by using p-type implant ions.

As illustrated in FIG. 2A to 21, charge traps remains in a gate dielectric layer in core circuit region (i.e. region i of region I). Due to the thinner gate dielectric layers 306a and 306b in region I (than in region A, a memory cell formed in region I has shorter charge retention time and perform similar to a dynamic random access memory (DRAM) cell. Similarly, charge traps remain in a gate dielectric layer in IO circuit region, i.e. region iii of region II. Thus, the memory cell formed with thicker gate dielectric in region iv can perform as a nonvolatile memory.

With the processes implemented as above, a resultant embedded semiconductor memory device can be illustrated in FIG. 2I. The embedded semiconductor memory device includes: a semiconductor substrate 301 comprising region I and region II, said region I being a core circuit region and including region i and region ii, said region II being an IO (Input and Output) circuit region and including region iii and region iv; the gate dielectric layers and the gate structures formed sequentially on the semiconductor substrate 301; the source/drain extension regions 407 formed respectively in region I and region II of the semiconductor substrate 301; and the source/drain regions 409 formed respectively in region I and region II of the semiconductor substrate 301, wherein upon application of a voltage to the gate structures, the respective source/drain regions 409 may be connected electrically through conductive channels formed in the semiconductor substrate 301, and the gate dielectric layers 306a in region i and the gate dielectric layer 306c in region iii may be charge trap regions (for memory cells), and the gate dielectric layer 306b in region ii and the gate dielectric layer 306d in region iv may be non-charge trap regions (for logic transistors).

A method for fabricating an embedded semiconductor memory device according to an embodiment of the invention includes: preparing a semiconductor substrate; forming a gate dielectric layer with charge traps formed therein and a gate structure on the semiconductor substrate sequentially; forming a source/drain extension region in the semiconductor substrate; forming a source/drain region in the semiconductor substrate; and applying a voltage to the gate structure, thus electrically connecting the source/drain region through conductive channels formed in the semiconductor substrate. In an embodiment of the invention, both n-type and p-type memory cells and logic transistors can be formed in core circuit region and/or IO circuit region, thus a complete embedded memory circuits (i.e. memory and logic circuits) can be formed together entirely with thinner gate dielectric (in core region) or entirely with thicker gate dielectric (in IO region) or a combination thereof. The embedded memory circuit with thinner gate dielectric can be operated with lower voltage, and similarly thicker gate dielectric for higher operating voltage. The embodiments shall not limit the invention thereto.

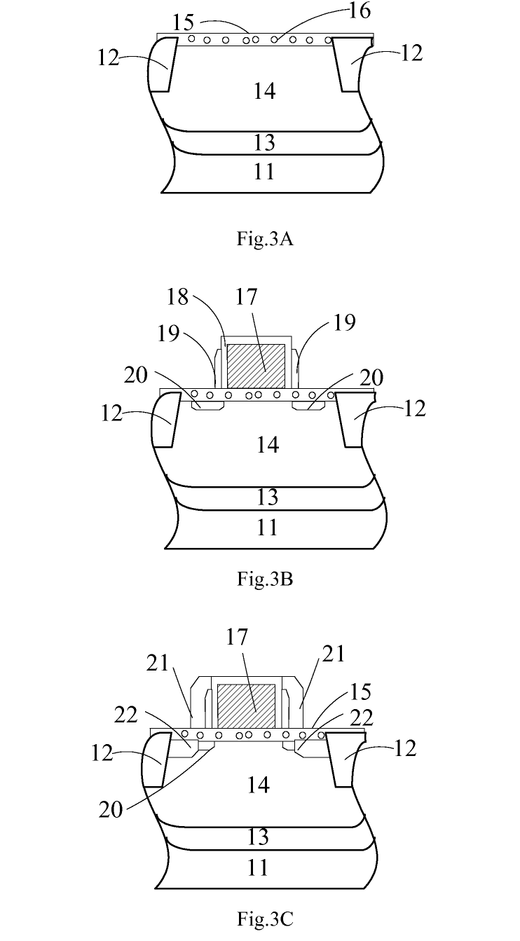

The method of fabrication MOS transistors according to a third embodiment of the invention is illustrated in FIG. 3A to 3C. Referring to FIG. 3A, shallow trenches 12 for isolating active devices electrically are formed on a semiconductor substrate 11, then a deep n-well region 13 and a p-well region 14 are formed. Next, a gate dielectric layer 15 is formed on the p-well 14 in the semiconductor substrate 11. The gate dielectric layer 15 is a high-k dielectric layer, such as HfO₂, Al₂O₃, La₂O₃, HfSiON or HfAlO₂, with inherent charge traps 16 therein, that is, the gate dielectric layer 15 has charge traps in it.

Referring to FIG. 3B, a gate structure 17 and a silicon oxide layer 18 are formed on the gate dielectric layer 15, then a first sidewall 19 is formed at each side of the gate structure 17, and next, source/drain extension regions 20 are formed at each side of the gate structure 17 in the semiconductor substrate 11 by ion implantation, where the implanted ions are arsenic, antimony, phosphorous or a combination thereof. In an embodiment of the invention, arsenic ions are preferably used in the ion implantation for forming the source/drain extension regions 20 for n-type memory cell.

Referring to FIG. 3C, a second sidewall 21 is formed on the first sidewall 19 at each side of the gate structure 17, and then source/drain regions 22 are formed at each side of the gate structure 17 in the semiconductor substrate 11.

With the processes implemented as above, a n-channel memory cell is resulted as illustrated in FIG. 3C includes: a semiconductor substrate 11; a gate dielectric layer 15 and a gate structure 17 sequentially formed on the semiconductor substrate 1; source/drain extension region 20 formed in the semiconductor substrate 11; and source/drain regions 22 formed in the semiconductor substrate 11, wherein source/drain regions 22 are electrically connected through conductive channels formed in the semiconductor substrate 11 when a voltage is applied to the gate structure 17; said gate dielectric layer 15 being charge traps region.

Correspondingly to FIGS. 3A to 3C, a p-channel memory cell structure can be formed by simply reverse the polarity of doping type on semiconductor regions, e.g. changing p-well 14 to n-well), changing n-type source/drain extension regions 20 to p-type source/drain extension regions), changing n-type source/drain regions 22 to p-type source/drain regions, and the deep n-well 13 remaining same or skip.

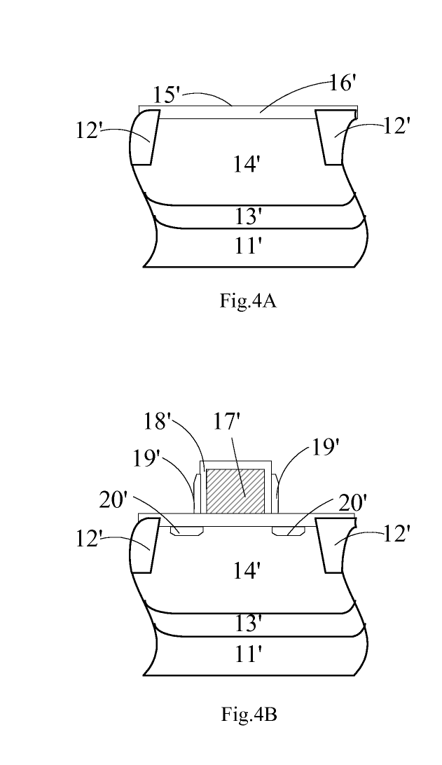

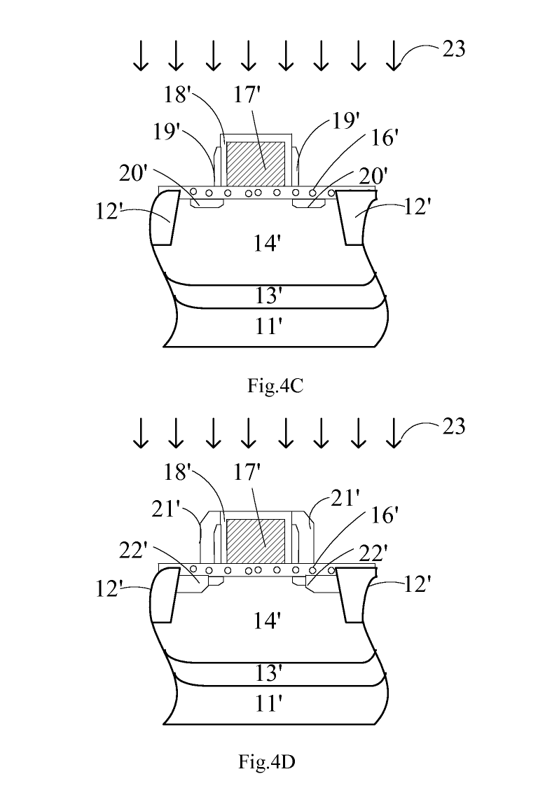

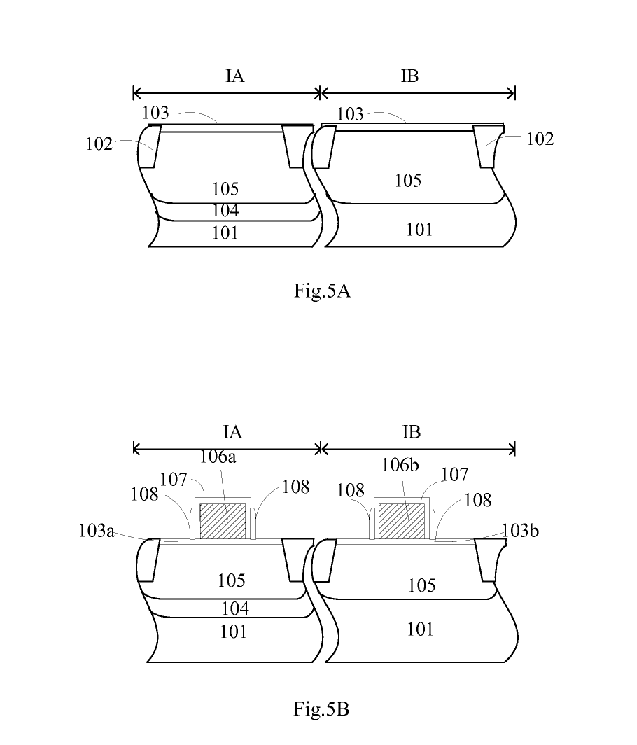

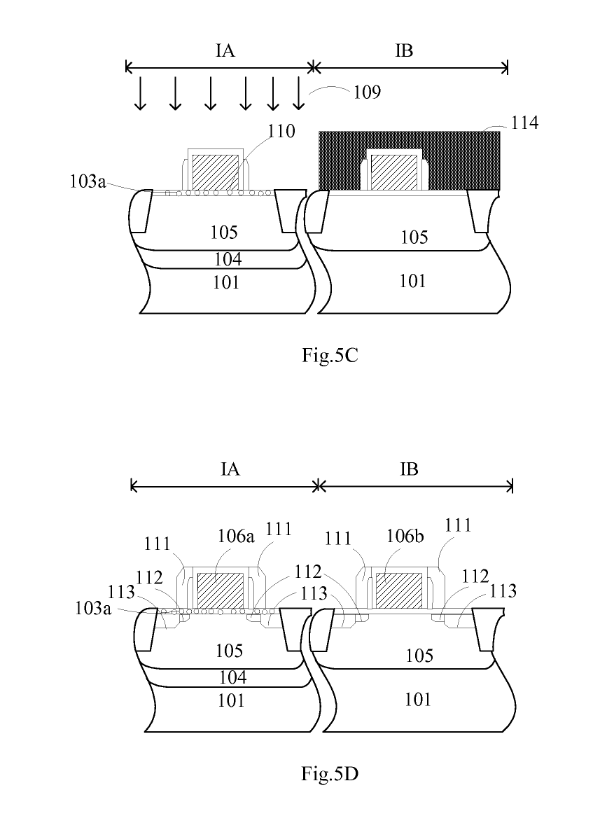

The method of fabrication MOS transistors according to a fourth embodiment of the invention is illustrated in FIGS. 4A to 4D. Referring to FIG. 4A, a method for fabricating a memory cells according to an embodiment of the invention includes: forming shallow trenches 12′ on a semiconductor substrate 11′; then forming a deep n-well region 13′ and a p-well region 14′ in the semiconductor substrate 11′; and next, forming a gate dielectric layer 15′ made of silicon oxide, silicon nitride (inherently no charge traps in it) or a combination thereof on the semiconductor substrate 11′.

Referring to FIG. 4B, a gate structure 17′ and a silicon oxide layer 18′ are formed on the gate dielectric layer 15′, then a first sidewall 19′ is formed at each side of the gate structure 17′, and next, source/drain extension regions 20′ are formed at each side of the gate structure 17′ in the semiconductor 11′.

Referring to FIG. 4C, an ion implantation 23 is performed in the gate dielectric layer 15′ and thus charge traps 16′ are formed in the gate dielectric layer 15′ where forms a charge trap region, the implanted ions during the ion implantation 23 are silicon ions, germanium ions, nitrogen ions or hafnium ions, the dosage of the ion implantation 23 ranges from 1.0E+11 to 1.0E+15 cm⁻², and the energy of the ion implantation 23 can be determined in accordance with the implanted ions and thickness of the gate structures. The charge traps 16′ are formed in the gate dielectric layer 15′ after the ion implantation 23 and subsequent annealing in process.

In an alternative embodiment, ions for the ion implantation 23 are nitrogen ions with an implantation dosage ranging from 1.0E+11 to 1.0E+15 cm⁻².

In another alternative embodiment, ions for the ion implantation 23 are germanium ions with an implantation dosage ranging from 1.0E+11 to 1.0E+13 cm⁻².

In another alternative embodiment, ions for the ion implantation 23 are silicon ions with an implantation dosage ranging from 1.0E+11 to 1.0E+13 cm⁻².

Referring to FIG. 4D, a second sidewall 21′ is formed on the first sidewall 19′ at each side of the gate structure 17′, and then source/drain regions 22′ are formed at each side of the gate structure 17′ in the semiconductor substrate 11.

With processes implemented as above, a resulted n-type channel memory cell as illustrated in FIG. 4D includes: a semiconductor substrate 11′; a gate dielectric layer 15′ and a gate structure 17′ sequentially formed on the semiconductor substrate 11′; source/drain extension regions 20′ formed in the semiconductor substrate 11′; and source/drain regions 22′ formed in the semiconductor substrate 11′, wherein source/drain regions 22′ are electrically connected through conductive channels formed in the semiconductor substrate 11′ when a voltage is applied to the gate structure; said gate dielectric layer 15′ being a charge trap region.

Correspondingly to FIGS. 4A to 4D, a p-channel memory cell structure can be formed by simply reversing the polarity of doping type on semiconductor regions, e.g. changing p-well 14 to n-well, changing n-type source/drain extension region 20 to p-type source/drain extension region, changing n-type source/drain region 22 to p-type source/drain region, while the deep n-well remaining same or skip.

The method of fabrication a memory cell and a logic transistor according to a fifth embodiment of the invention is illustrated in FIGS. 5A to 5D. In an embodiment of the invention, a method for fabricating an embedded semiconductor memory device includes: preparing a semiconductor substrate comprising region IA and IB; forming gate dielectric layers and gate structures on the substrate sequentially; and forming source/drain extension regions respectively in region IA and IB of the substrate; and forming source/drain regions respectively in region IA and IB of the substrate, wherein the source/drain regions are electrically connected through respective conductive channel formed in the substrate, and charge traps are formed in the gate dielectric layer in region IA (for memory cells) and no charge traps are formed in the gate dielectric layer in region IB (for logic transistors).

Referring to FIG. 5A, a semiconductor substrate 101 comprising region IA and IB is prepared, then shallow trenches 102 are formed in a semiconductor substrate 101, next, a deep n-well region 104 and p-well regions 105 are formed in the semiconductor substrate 101, and then a gate dielectric layer 103 (referred to as 103a and 103b for gate dielectric layer in IA and IB respectively) made of silicon oxide, silicon nitride or a combination thereof are formed on the semiconductor substrate 101.

Referring to FIG. 5B, gate structures 106a and 106b are formed in region IA and IB of the semiconductor substrate 101 respectively, then a silicon oxide layer 107 is formed on the gate structures 106a and 106b, and then a first sidewall 108 is formed at each side of the gate structures 106a and 106b.

Referring to FIG. 5C, a photoresist mask 114 opens region IA and covers region IB. An ion implantation 109 is performed in the gate dielectric layer 103 in region IA to form charge traps 110, where the implanted ions are silicon ions, germanium ions, nitrogen ions or hafnium ions, the implantation dosage ranges from 1.0E+11 to 1.0E+15 cm⁻², and the implantation energy is determined in accordance with the implanted ions and the height of the gate structures. The charge traps 110 are formed in the gate dielectric layer 103a after the ion implantation 109 and subsequent annealing in process, thus the dielectric layer 103a forms a charge trap region for memory cells, while the gate dielectric layer 103b forms a non-charge trap region for logic transistors.

In an alternative embodiment, ions for the ion implantation 109 are nitrogen ions with an implantation dosage ranging from 1.0E+11 to 1.0E+15 cm⁻².

In another alternative embodiment, ions for the ion implantation 109 are germanium ions with an implantation dosage ranging from 1.0E+11 to 1.0E+15 cm⁻².

Referring to FIG. 5D, source/drain extension regions 112 are formed on each side of the gate structures 106a and 106b on the semiconductor substrate 101, then a second sidewall 111 is formed on the first sidewall 108 on each side of the gate structures 106a and 106b, and next, source/drain regions 113 are formed on each side of the gate structures 106a and 106b of the semiconductor substrate 101.

With the processes implemented as above, a structure of the embedded semiconductor memory device including a memory cell and a logic transistor is resulted as illustrated in FIG. 5D includes: the semiconductor substrate 101 comprising region IA and region IB; the gate dielectric layers 103a and 103b and the gate structures 106a and 106b sequentially formed on the semiconductor substrate 101; source/drain extension regions 112 formed in region IA and region IB of the semiconductor substrate 101 respectively; and source/drain regions 113 formed in region IA and IB of the semiconductor substrate 101 respectively. When a voltage is applied to the gate structures 106a and 106b, source/drain regions 113 are electrically connected through respective conductive channels formed in the semiconductor substrate 101. The gate dielectric layer 103a in region IA has charge traps for memory cell and the gate dielectric 103b in region IB has non-charge traps for logic transistor. Thus, region IA can form a memory cell, and region IB can form a logic transistor.

Correspondingly to FIG. 5A to 5D, a p-channel memory cell and logic transistor structure can be formed by simply reversing the polarity of doping type on semiconductor regions, e.g. changing p-well 105 to n-well, changing n-type source/drain extension regions 112 to p-type source/drain extension regions, changing n-type source/drain regions 113 to p-type source/drain regions, while deep n-well 104 remaining same or skip.

Furthermore, with both n-channel and p-channel memory cells and logic transistors formed by the structures illustrated in FIGS. 5A to 5D, a complete embedded memory circuits (or SOC) can be readily formed.

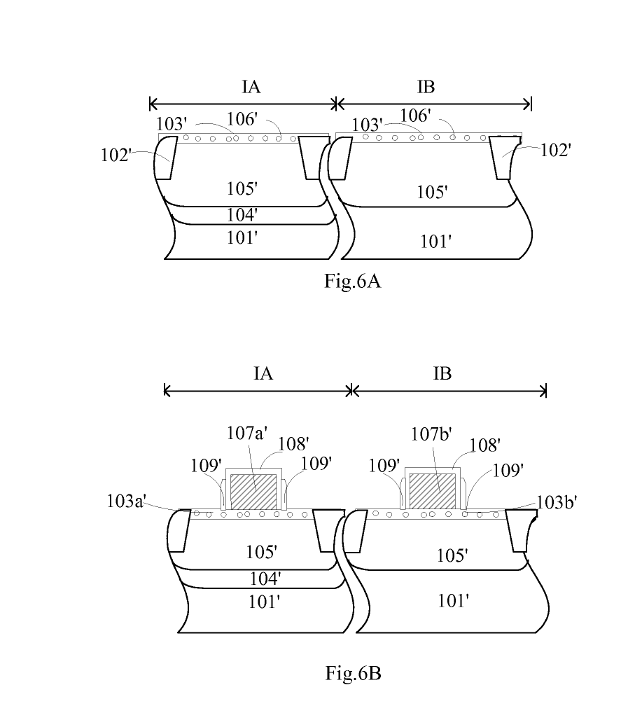

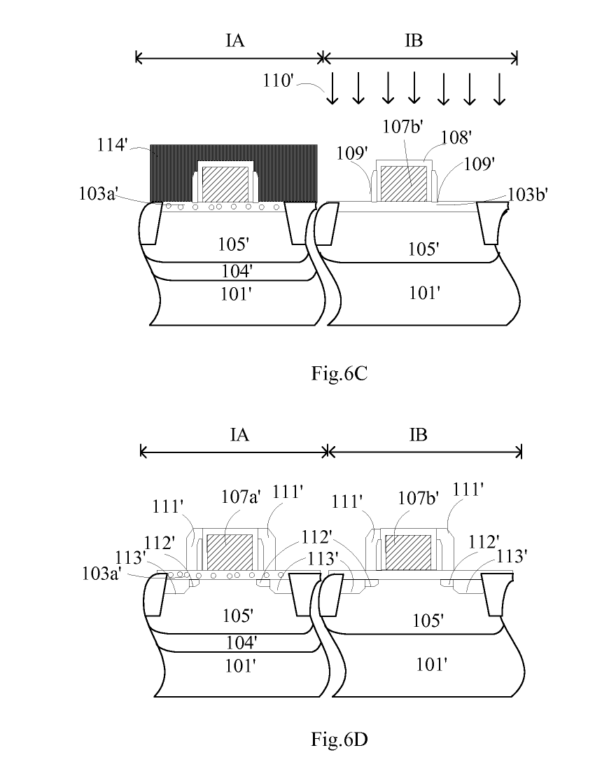

The method of fabrication MOS transistors according to a sixth embodiment of the invention is illustrated in FIG. 6A to 6D. Referring to FIG. 6A, a method for fabricating a memory cell according to an embodiment of the invention includes: preparing a semiconductor substrate 101′ comprising region IA and region IB; forming shallow trenches 102′ on the semiconductor substrate 101′; forming a deep n-well region 104′ and a p-well region 105′ in the semiconductor substrate 101′; and forming gate dielectric layers 103′ (referred to as 103a′ and 103b′ in region IA and IB respectively) made of a high-k dielectric material on the semiconductor substrate 101′, such as HfO₂, Al₂O₃, La₂O₃, HfSiON or HfAlO₂, with charge traps 106′ therein inherently,.

Referring to FIG. 6B, gate structures 107a′ and 107b′ are formed in regions IA and IB of the semiconductor substrate 101′, then a silicon oxide layer 18 is formed on the gate structures 107a′ and 107b′, and next a first sidewall 109′ is formed on each side of the gate structures 107a′ and 107b′.

Referring to FIG. 6C, a photoresist mask 114′ opens region IB (and cover region IA), and then an ion implantation 110′ is performed where the ions for the ion implantation 110′ are fluorine or nitrogen. The energy for the ion implantation 110′ can be determined in accordance with the implanted ions and the height of the gate structure 107b′, and the implantation dosage for the ion implantation 110′ ranges from 1.0E+11 to 1.0E+15 cm⁻². The charge traps 106′ in the gate dielectric layer 103b′ can be eliminated effectively after the implantation 110′ and subsequent annealing process, thus region IB is suitable for logic transistors. Then the photo-resist mask 114′ is removed.

In a preferable embodiment of the present invention, ions for the ion implantation 110′ are fluorine with an implantation energy ranging from 50 to 200 KeV and an implantation dosage ranging from 1.0E+11 to 1.0E+15 cm⁻². The charge traps 106′ in the gate dielectric layer 103b′ below the gate structure 107b′ are reduced or even eliminated.

In another preferable embodiment of the present invention, ions for the ion implantation 110′ are nitrogen with an implantation energy ranging from 50 to 200 KeV and dosage ranging from 1.0E+11 to 1.0E+15 cm⁻². The charge traps 106′ in the gate dielectric layer 103b′ underneath the gate structure 107b′ are reduced or even eliminated.

Referring to FIG. 6D, source/drain extension regions 112′ are formed at each side of the gate structures 107a′ and 107b′ of the semiconductor substrate 101′, then a second sidewall 111′ is formed on the first sidewall 109′ at each side of the gate structures 107a′ and 107b′, and next source/drain regions 113′ is formed at each side of the gate structures 107a′ and 107b′ of the semiconductor substrate 101′.

With the processes implemented as above, the embedded semiconductor memory device including both a memory cell and a logic transistor structures are resulted as illustrated in FIG. 6D and include: a semiconductor substrate 101′ comprising region IA and IB; gate dielectric layers 103a′ and 103b′ and gate structures 107a′ and 107b′ sequentially formed on the semiconductor substrate 101′; source/drain extension regions 112′ formed in region IA and IB respectively; and source/drain regions 113′ formed respectively in region IA and IB; when a voltage is applied to the gate structures, source/drain regions 113′ are electrically connected through respective conductive channels formed in the semiconductor substrate 101′, the gate dielectric layer 103a′ in region IA has charge traps and is for memory cells, and the gate dielectric 103b′ in region IB has no charge traps for logic transistors.

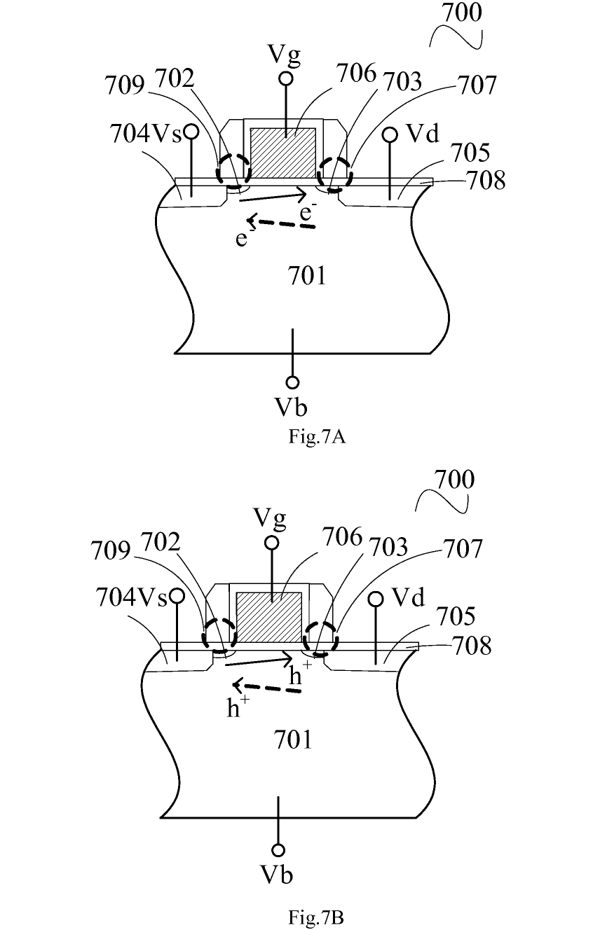

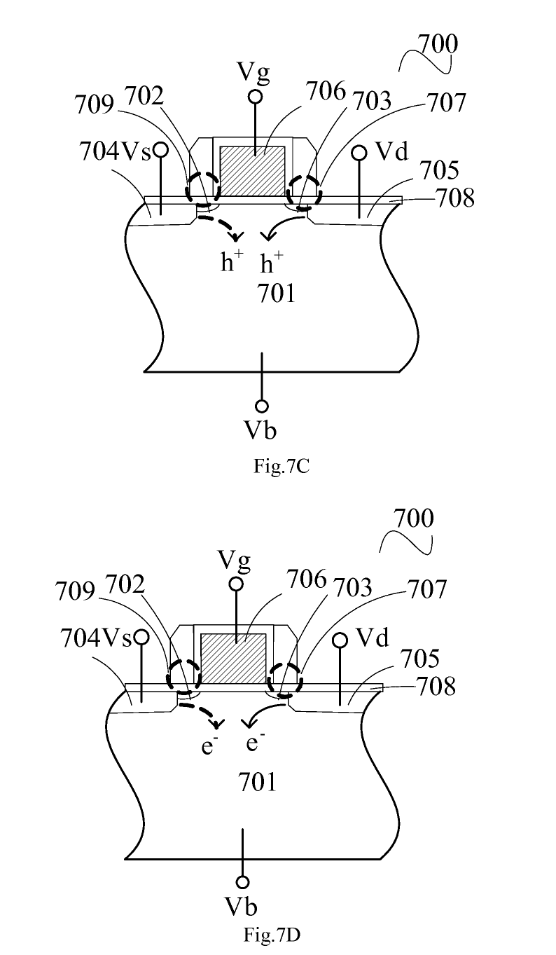

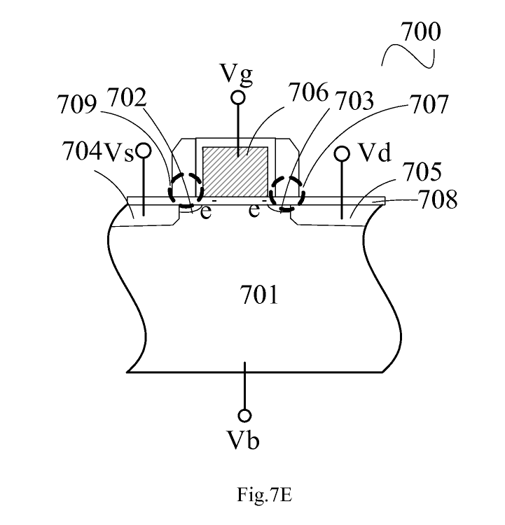

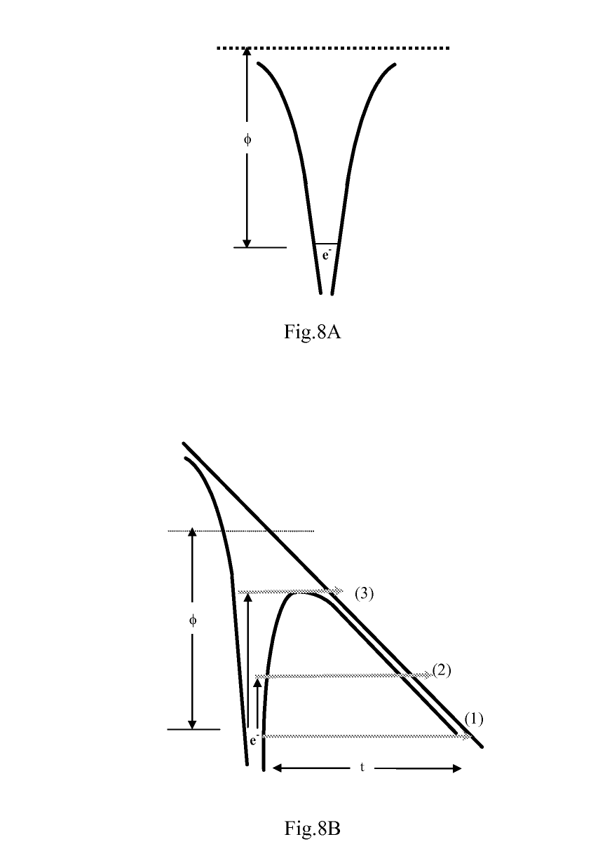

The operation modes of memory cell are described in FIG. 7A to 7E. Programming and erasing can be performed for a memory cell according to an embodiment of the invention through an injection of channel-hot carriers or band-to-band induced hot carriers. Hereinafter, operation principles for programming, reading, and erasing will be described according to an embodiment of the invention.

FIG. 7A illustrates an n-type memory cell 700, which includes: a substrate 701 (representing the p-well as illustrated above); a source extension region 702, a drain extension region 703, a source region 704 and a drain region 705; and a gate dielectric layer 708 and a gate structure 706. A gate voltage Vg is applied to the gate structure 706 of the memory cell 701 through a row word-line circuitry, a source voltage Vs to the source region 704 through source column circuitry, a drain voltage Vd to the drain region 705 through drain column circuitry, and a bulk voltage Vb to the substrate 701 respectively through a peripheral circuit.

In an embodiment of the invention, the operation of programming an n-type memory cell 700 can be performed through channel-hot electrons as illustrated in FIG. 7A. In an embodiment of the invention, the gate voltage Vg is 3.3V, the drain voltage Vd is 3.3V, the source voltage Vs is 0V, and the bulk voltage Vb is 0V. Upon application of the drain voltage Vd, since the PN junction formed between the drain extension region 702 and the substrate 701 is relatively narrow, a strong electric field is formed in the channel and the PN junction near the drain region 705. Electrons generated in the channel are accelerated by the strong electric field in the PN junction when the electrons approach the PN junction near the drain region 705 and thus become hot electrons. Then the number of hot electrons is multiplied exponentially near the drain region 705 due to the well-known impact ionization mechanism. The hot electrons are high enough in energy that they can overcome the interface barrier to reach the gate dielectric near the drain end 707 according to a well-known “hot electron injection” mechanism. At the same time, holes generated near the drain region 705 are flowing toward the bulk voltage Vb biased at 0V. An arrow of a solid line in FIG. 7A indicates the direction of electron flow from the source toward the drain end 707.

Similarly, in another alternative embodiment of the invention, the drain voltage Vd and the source voltage Vs are exchanged. For example, the drain voltage Vd is 0V, the source voltage Vs is 3.3V, the gate voltage Vg is 3.3V, and the bulk voltage Vb is 0V. The electrons generated in the channel are accelerated by the strong electric field in the PN junction when the electrons approach the PN junction near the source region 704 and thus become hot electrons. The number of the electrons can increase exponentially near the source region 704 due to the impact ionization mechanism. The hot electrons have high enough energy to overcome the interface barrier to reach the gate dielectric at source end 709. An arrow of a dotted line in FIG. 7A indicates the direction of electrons flow from drain into the source end 709.

A two-bit storage for the n-channel memory cell 700 can be realized by sequentially applying positive source and drain voltages Vs and Vd in an embodiment of the invention.

In the case of a p-channel memory cell 700, the operation of programming can be performed through channel-hot holes injection as illustrated in FIG. 7B. In an alternative embodiment of the invention, the gate voltage Vg is 0V, the drain voltage Vd is 0V, the source voltage Vs is 3.3V, and the bulk voltage Vb is 3.3V Since a PN junction formed between the source extension region 702 and the substrate 701 is relatively narrow, a strong electric field can be formed in the channel and the PN junction near the source region 704, and holes generated in the channel can be accelerated by the strong electric field in the PN junction near the source region 704 and thus become hot holes when approach the drain region 705. The number of the hot holes multiplies exponentially near the drain region 705 due to the impact ionization mechanism. The hot holes have high enough energy to overcome the interface barrier to enter into the gate dielectric near the drain end 707 according to hot hole injection mechanism. At the same time, electrons generated near the drain region 705 are flowing toward the bulk voltage Vb at 3.3V An arrow of solid line in FIG. 7B indicates the direction of holes flowing into the drain end 707.

Similarly, in another alternative embodiment of the invention, the drain voltage Vd and the source voltage Vs are exchanged. For example, the drain voltage Vd is 3.3V, the source voltage Vs is 0V, the gate voltage Vg is 0V, and the bulk voltage Vb is 3.3V Thus, holes generated in the channel are accelerated by the drain voltage Vd and thus become hot holes. The number of the hot holes is multiplied exponentially near the source region 704 due to the impact ionization mechanism. The hot holes have high enough energy to overcome the interface barrier to reach the gate dielectric near source end 709 according to the channel hot hole injection. An arrow of a dotted line in FIG. 7B indicates the direction of holes flowing into the source end 709.

A two-bit storage for the p-channel memory cell 700 can be realized through sequentially applying positive source voltage Vs (with Vd at 0 v) and positive drain voltage Vd (with Vs at 0 v) in an embodiment of the invention.

In an embodiment of the invention, programming the memory cell 700 can also be performed through local charge injection by band-to-band tunneling induced hot carriers, which will be described in detail hereinafter.

Referring to FIG. 7C, the memory cell 700 is a n-type channel. In order to store data into the memory cell 700, a gate voltage Vg can be set at 0V, and thus no inversion electrons is formed in the channel according to a programming principle for the memory cell 700. Then, the data are stored in the memory cell 700 by applying a positive drain voltage Vd or a positive voltage Vs to the drain region 705 or to the source region 704 through a column bit line by a peripheral circuit. When the drain voltage Vd or the source voltage Vs is applied, holes near the drain extension region 703 or the source extension region 702 in the semiconductor substrate 701 get to the surface of the drain region 705 or the source region 704 through a band-to-band tunneling mechanism. The holes at the surface of the drain region 705 or the source region 704 can flow into the semiconductor substrate 701 under the bulk voltage Vb. The holes at the surface of the drain region 705 or the source region 704 are accelerated by the strong electric field in the PN junction when passing the PN junction near the drain region 705 or the source region 704, and thus become hot holes. Meanwhile, more electron-hole pairs are generated through ionization effect. These hot holes have high enough energy to overcome the interface barrier to reach the drain end 707 or the source end 709 in the gate dielectric layer 708.

In an embodiment of the invention, the gate voltage Vg is 0V, the drain voltage Vd is 3.3V, the source region is floated, and the bulk voltage Vb is 0V. Thus, holes are generated near the drain end 707 through the band-to-band tunneling mechanism. The holes are accelerated by the strong electric field of the PN junction when they flow into the semiconductor substrate 701, and thus become hot holes. Furthermore, more electron-hole pairs are generated by these hot holes through ionization effect. The generated holes can overcome the interface barrier to enter the drain end 707 in the gate dielectric layer 708. An arrow of a solid line in FIG. 7C indicates a direction that a holes flow into the drain end 701.

In another alternative embodiment of the invention, the gate voltage Vg is 0V, the drain region is floated, the source voltage Vs is 3.3V, and the bulk voltage Vb is 0V. Thus, holes are generated near the source end 709 through the band-to-band tunneling mechanism. The holes are accelerated by the strong electric field in the PN junction when flowing toward the semiconductor substrate 701, and thus become hot holes, more electron-hole pairs are generated by these hot holes through ionization effect. The generated holes can overcome the interface barrier to reach the source end 709 in the gate dielectric layer 708. An arrow of a dotted line in FIG. 7C indicates a direction that holes flow into the drain end 701.

A two-bit storage for the n-channel memory cell 700 can be realized through simultaneously applying positive source and drain voltages Vs and Vd in an embodiment of the invention.

In the case of a p-type channel memory cell 700 with reference to FIG. 7D, in order to store data into the memory cell 700, the gate voltage Vg and the bulk voltage Vb can be set at 3.3V, and thus no inversion holes is formed in the channel. Then, the needed data are stored into the memory device cell 700 by applying a voltage of 0V to the drain region 705 or the source region 704 through a column bit line by peripheral circuit. Electrons near the drain extension region 702 or the source extension region 703 in the semiconductor substrate 701 can reach the surface of the drain region 705 or the source region 704 through the band-to-band tunneling mechanism. Since the PN junction formed between the drain extension region 702 or the source extension region 703 and the substrate 701 is relatively narrow, the electric field in the PN junction is strong, and the electrons are accelerated by the strong electric field in the PN junction when flowing back to the semiconductor substrate 701, thus becoming hot electrons. Then, more electron-hole pairs are generated through ionization effect. The generated electrons have high enough energy to overcome the interface barrier to reach the drain end 707 or the source end 709 in the gate dielectric layer 708.

In an alternative embodiment of the invention, the gate voltage Vg is 3.3V, the drain voltage Vd is 0V, the source region is floated, and the semiconductor substrate voltage Vb is 3.3V Thus, electrons are generated near the drain end 707 through the band-to-band tunneling mechanism. The electrons are accelerated by the strong electric field in the PN junction when flowing into the semiconductor substrate 701, and thus generate hot electrons. These hot electrons generate more electron-hole pairs through impact ionization mechanism. The generated electrons can overcome the interface barrier to reach the drain end 707 in the gate dielectric layer 708. An arrow of a solid line in FIG. 7D indicates the direction of electrons flowing into the substrate 701.

In another alternative embodiment of the invention, the gate structure voltage Vg is 3.3V, the drain region is floated, the source voltage Vs is 0V, and the semiconductor substrate voltage Vb is 3.3V Thus, electrons are generated near the source end 709 through the band-to-band tunneling mechanism. The electrons are accelerated by the strong electric field in the PN junction when flowing toward the semiconductor substrate 701, and thus generate hot electrons. Furthermore, more electron-hole pairs are generated by these hot electrons generate through ionization effect. The generated electrons can overcome the interface barrier to reach the source end 709 in the gate dielectric layer 708. An arrow of a dotted line in FIG. 7D indicates the direction of electrons flowing into the drain end 701.

A two-bit storage for the p-channel memory cell 700 can be realized through simultaneously applying positive source and drain voltages Vs and Vd in an embodiment of the invention.

As described in above, for a one-bit memory cell, in the case of only charge traps for electrons existing in the gate dielectric layer 708: for the n-channel memory cell 700 , the programming operation can be performed through a Channel Hot Electron (CHE) injection (the electrons are stored into the charge traps in the gate dielectric layer 708), and the erasing operation can be performed through a Band-to-Band Tunneling (BBT) hole injection (the holes are injected into the charge traps to neutralize the electrons); similarly, for a p-channel memory cell 700, the operations can be performed through the BBT electron injection (the electrons are stored into the charge traps in the gate dielectric layer 708) and the CHE hot hole implantation (the holes are injected into the charge traps to neutralize the electrons), respectively. The one-bit programming and erasing operations play an important role in the function of an Electrically Erasable Programmable Read Only Memory (EEPROM).

From above, if there is only one type of trap charges existing in the gate dielectric layer 708, the erasing operation can be performed to a whole memory block simply through Fowler-Nordheim (F-N) tunneling or direct tunneling (with proper biasing for hole injection toward traps, or electrons tunneling out of traps) until all charge traps are empty (i.e. without over-erasing bits). However, if both types of traps co-exist, then there will be over-erase as the local net charge will continuously be “erased” from initial negative toward positive charge. The control of dielectric layer material and the nature of traps are essential to the erase methods to be implementation.

Reading of the memory cell 700 can be performed by measuring channel current. Referring to FIG. 7E, in the case of the n- channel memory cell 700, a voltage is applied on the gate structure 706 through a row word line circuit and an electron channel is generated below the gate structure 706. Then the drain voltage Vd is applied and the source voltage Vs is set as 0V through a column bit line circuitry. If the source end 707 of the memory cell 700 has been programmed and thus stores negative charges, then a drain current Id of the memory cell 700 can be relatively small (<1 μA), otherwise, the drain current Id of the memory cell 700 can be relatively large (>10 μA). Similarly, the source voltage Vs is applied by the source column circuitry and the drain voltage Vd is set as 0V. If the drain end 709 of the memory cell 700 has been programmed, and thus stores negative charges, then a source current Is of the memory cell 700 can be relatively small (<1 μA), otherwise the source current Is of the memory cell 700 can be relatively large (>10 μA).

Through detecting the drain current Id (by applying a forward voltage) and the source current Is (by applying a reverse voltage) sequentially, two-bit data can be read from the memory cell 700. Similarly, data can be read from a p-type channel memory cell 700.

In an alternative embodiment of the invention, the gate voltage Vg is 3.3V, the drain voltage Vd is IV, the source voltage Vs is 0V, and the bulk voltage Vb is 0V. If the drain end 709 of the memory cell 700 has been programmed and thus stores negative charges, then a drain current Id can be relatively small (<1 μA), otherwise the drain current Id of the memory cell 700 can be relatively large (>10 μA).

In another alternative embodiment of the invention, the gate voltage Vg is 3.3V, the drain voltage Vd is 1V, the source voltage Vs is 0V, and the bulk voltage Vb is 0V. If the source end 707 of the memory cell 700 has been programmed, then a source current Is can be relatively large (>10 μA), otherwise the source current Is of the memory cell 700 can be relatively small (<1 μA).

Alternatively, reading of the memory cell 700 can be performed through band-to-band tunneling currents (or GIDL, gate induced drain leakage) In the case of the n-channel memory cell, the gate voltage Vg is 0V, and hence no reversion electrons exists in the channel. A positive drain voltages Vd or source voltage Vs can be applied to the drain region 705 or the source region 704 through a column bit line by the peripheral circuit. If the drain end 709 or the source end 707 of the memory device cell 700 has been programmed, and thus stores negative charges, then a drain and a source current Id and Is of the memory cell 700 can be relatively small (<0.1 μA), otherwise the drain and the source current Id and Is of the memory cell 700 can be relatively large (>1 μA), where the drain and source currents Id and Is can be measured simultaneously. Similarly, in the case of a p-channel memory cell 700, a negative drain voltage Vd or a negative source voltage Vs can be applied to the drain region 705 or to the source region 704 by the peripheral circuit. If the drain end 709 and the source end 707 of the memory cell 700 has been programmed, and thus stores negative charges, then a drain and a source current Id and Is of the memory cell 700 can be relatively small (<0.1 μA), otherwise the drain or source current Id or Is of the memory cell 700 can be relatively large (>1 μA).

In an alternative embodiment of the invention, for an n-type channel memory cell 700, the gate voltage Vg is 0V, the drain voltage Vd is 1V, the drain voltage is 1V, and the bulk voltage Vb is 0V. If the drain end 707 and the source end 709 of the memory cell 700 have been programmed, and thus store negative charges, then a drain and a source current Id and Is of the memory cell 700 can be relatively small (<0.1 μA).

In an alternative embodiment of the invention, for a p-type channel memory cell 700, the gate voltage Vg and the bulk voltage Vb are 0V, the drain voltage is −1V, and the source voltage Vs is −1V If the drain end 707 and the source end 709 of the memory cell 700 have been programmed, and thus store negative charges, then a drain and a source current Id and Is of the memory cell 700 can be relatively small (<0.1 μA).

The charge retention of memory cell is illustrated in FIG. 8A-8B. FIG. 8A illustrates an energy diagram of electrons trapped in a gate dielectric layer, where φ is potential energy, and a horizontal dotted line indicates that electric field in the gate dielectric layer and the semiconductor substrate is zero (Vg=Vb=0). Referring to FIG. 8B, upon application of a bulk voltage to the semiconductor substrate, a slope of the energy band indicates the intensity of electric field, and the electrons trapped in the gate dielectric layer may be escaping through three possible mechanism: (1) direct tunneling with a tunneling length t, where the tunneling length t is dependent on a physical position and an internal electric field; (2) thermally assisted tunneling, where the tunneling length t can be effectively reduced due to elevated temperature and thermal energy; and (3) thermal ionization. As seen from the figure, using a high-k material (e.g. hafnium oxide with a dielectric constant ranging from 15 to 25) can lead to an effectively increase the tunneling length t (e.g. silicon oxide or silicon nitride with a dielectric constant ranging from 4 to 8) at a given thickness of the gate dielectric layer. Consequently, the retention time of charges trapped in the gate dielectric layer is related to the trap barrier (φ), temperature, tunneling length t, and the intensity of electric field during the retention, etc.

In the first embodiment of the invention, the charge traps can be formed in the gate dielectric layer of the MOS transistor in region I (i.e. a core circuit region) so as to form a core memory cell region, and the charge traps can be formed in the gate dielectric layer of the MOS transistor in region II so as to form an IO memory cell region. Since the gate dielectric layer in the core circuit region is relatively thin, and the tunneling length “T” is relatively small in magnitude correspondingly as illustrated in FIG. 8B, thus the charges in the traps are easily to escape from the trap, therefore the retention time in the core memory cell region can be relatively short, so the semiconductor memory cell can perform similarly as a random access memory (DRAM) cell. On the other hand, since the gate dielectric layer in the IO circuit region is relatively thick, and the tunneling length t is relatively large correspondingly as illustrated in FIG. 8B, it is difficult for the charges trapped to escape the traps, and the retention time in the IO memory cell region can be relatively long, and the embedded semiconductor memory device can perform similarly as a nonvolatile memory device.

The present invention has been described and illustrated with reference to the embodiments thereof and the drawings. However, it shall be recognized by those skilled in the art that those embodiments and drawings are merely illustrative and not restrictive, that the present invention shall not be limited thereto, and that various modifications and variations can be made thereto in light of the descriptions and the drawings without departing from the spirit and scope of the present invention as defined in the accompanying claims.

What is claimed is:

1. A method for fabricating an embedded semiconductor memory device, comprising:
preparing a semiconductor substrate comprising region IA and region IB;
forming gate dielectric layers and gate structures sequentially on the semiconductor substrate, with the gate dielectric layers in region IA being a charge trap region, and the gate dielectric layers in region IB being a non-charge trap region;
forming source/drain extension regions in region IA and region IB; and
forming source/drain regions in region IA and region IB, wherein upon application of a voltage to the gate structures, the respective source/drain regions are electrically connected through channels formed in the semiconductor substrate.

2. The method for fabricating an embedded semiconductor memory device according to claim 1, wherein the formation of the gate dielectric layers further comprises: forming a high-k dielectric layer on the semiconductor substrate as the gate dielectric layer, such as HfO₂, Al₂O₃, La₂O₃, HfSiON or HfAlO₂, with charge traps therein; and performing an ion implantation in the gate dielectric layer in region IB to eliminate the charge traps, thus forming a non-charge trap region in the gate dielectric layer in region IB and a charge trap region in the gate dielectric layer in region IA.

3. The method for fabricating an embedded semiconductor memory device according to claim 2, wherein the implanted ions are fluorine ions or nitrogen ions, the implantation energy is determined in accordance with thickness of the gate structures and the gate dielectric layers, and the implantation dosage ranges from 1.0E+11 to 1.0E+15 cm⁻².

4. The method for fabricating an embedded semiconductor memory device according to claim 1, wherein the formation of the gate dielectric layers further comprises: forming the gate dielectric layers on the semiconductor substrate, said gate dielectric layers comprising silicon oxide, silicon nitride or a combination thereof, performing an ion implantation in the gate dielectric layer in region IA to generate charge traps, thus forming a charge trap region in the gate dielectric layer in region IA and a non-charge trap region in the gate dielectric layer in region IB.

5. The method for fabricating an embedded semiconductor memory device according to claim 4, wherein the implanted ions are silicon ions, germanium, nitrogen or hafnium ions, the implantation dosage ranges from 1.0E+11 to 1.0E+13 cm⁻², the implantation energy is determined in accordance with the implanted ions and thickness of the gate structures, and the implantation angle ranges from 0° to 60°.

6. The method for fabricating an embedded semiconductor memory device according to claim 1, wherein the channel of the embedded semiconductor memory device is an n-type or a p-type, the ions implanted into the source/drain extension region of the n-type channel embedded semiconductor memory device are arsenic or antimony or phosphorous ions, and the ions implanted into the source/drain extension region of the p-type channel embedded semiconductor memory device are indium or boron ions.

7. An embedded semiconductor memory device, comprising:
a semiconductor substrate comprising region IA and region IB;
gate dielectric layers and gate structures formed sequentially on the semiconductor substrate;
source/drain extension regions formed in region IA and region IB; and
source/drain regions formed in region IA and region IB, wherein upon application of a voltage to the gate structures, the respective source/drain regions are electrically connected through conductive channels formed in the semiconductor substrate;
wherein the gate dielectric layer in region IA is a charge trap region, and the gate dielectric layer in region IB is a non-charge trap region.

8. The embedded semiconductor memory device according to claim 7, wherein the gate dielectric layers are high-k dielectric material, such as HfO₂, Al₂O₃, La₂O₃, HfSiON or HfAlO₂, with charge traps therein, the gate dielectric layer in region IB forms a non-charge trap region by an ion implantation to eliminate the charge traps, and the gate dielectric layer in region IA forms a charge trap region.

9. The embedded semiconductor memory device according to claim 8, wherein the implanted ions are fluorine ions or nitrogen ions, the implantation energy is determined in accordance with thickness of the gate structures and the gate dielectric layers, and the implantation dosage ranges from 1.0E+11 to 1.0E+15 cm⁻².

10. The embedded semiconductor memory device according to claim 7, wherein the gate dielectric layers comprise silicon oxide, silicon nitride or a combination thereof, the gate dielectric layers in region IA forms a charge trap region by an ion implantation, and the gate dielectric layer in region IB forms a non-charge trap region.

11. The embedded semiconductor memory device according to claim 10, wherein the implanted ions are silicon ions, germanium ions, nitrogen ions or hafnium ions, the implantation dosage ranges from 1.0E+11 to 1.0E+13 cm⁻², the implantation energy is determined in accordance with the implanted ions and thickness of the gate structures, and the implantation angle ranges from 0° to 60°.

12. The embedded semiconductor memory device according to claim 7, wherein the channel of an embedded semiconductor memory device is an n-type or a p-type, the ions implanted into the source/drain extension regions of the n-type channel embedded semiconductor memory device are arsenic ions or antimony ions or phosphorous ions, and the ions implanted into the source/drain extension regions of the p-type channel embedded semiconductor memory device are indium ions or boron ions.

13. A method for fabricating an embedded semiconductor memory device, comprising:
preparing a semiconductor substrate comprising region I and region II, said region I being a core circuit region and including region i and region ii, said region II being an IO (Input and Output) circuit region and comprising region iii and region iv;
forming gate dielectric layers and gate structures sequentially in region I and region II of the semiconductor substrate, with the gate dielectric layers in region i and/or region iii being a charge trap region, and the gate dielectric layers in region ii and/or region iv being a non-charge trap region;
forming source/drain extension regions in region I and region II; and
forming source/drain regions in region I and region II respectively, wherein upon application of a voltage to the gate structures, the respective source/drain regions are electrically connected through conductive channels formed in the semiconductor substrate.

14. The method for fabricating an embedded semiconductor memory device according to claim 13, wherein the formation of the gate dielectric layers may further comprises: forming a high-k dielectric layer on the semiconductor substrate as the gate dielectric layers, such as HfO₂, Al₂O₃, La₂O₃, HfSiON or HfAlO₂, with charge traps therein; and performing a first ion implantation and/or a second ion implantation in the gate dielectric layer in region ii and/or region iv to eliminate the charge traps, thus forming a non-charge trap region in region ii and/or region iv and a charge trap region in the gate dielectric layer in region i and/or region iii.

15. The method for fabricating an embedded semiconductor memory device according to claim 14, wherein the ions for the first ion implantation and/or the second ion implantation are fluorine ions or nitrogen ions, the implantation energy for the first ion implantation and/or the second ion implantation is determined in accordance with the implanted ions and thickness of the gate structures, and the implantation dosage for the first ion implantation and/or the second ion implantation ranges from 1.0E+11 to 1.0E+15 cm⁻².

16. The method for fabricating an embedded semiconductor memory device according to claim 13, wherein the formation of the gate dielectric layers further comprises: forming the gate dielectric layers on the semiconductor substrate, said gate dielectric layers comprising silicon oxide, silicon nitride or a combination thereof, and performing a first ion implantation and/or a second ion implantation in the gate dielectric layer in region i and/or region iii to generate charge traps, thus forming a charge trap region in region i and/or region iii and a non-charge trap region in region ii and/or region iv.

17. The method for fabricating an embedded semiconductor memory device according to claim 16, wherein the ions for the first ion implantation and/or the second ion implantation are silicon ions, germanium ions, nitrogen ions or hafnium ions, the implantation dosage for the first ion implantation and/or the second ion implantation ranges from 1.0E+11 to 1.0E+13 cm⁻², the implantation energy for the first ion implantation and/or the second ion implantation is determined in accordance with the implanted ions and thickness of the gate structures, and the implantation angle for the first ion implantation and/or the second ion implantation ranges from 0° to 60°.

18. The method for fabricating an embedded semiconductor memory device according to claim 13, wherein the channel of an embedded semiconductor memory device is an n-type or a p-type, the ions implanted into the source/drain extension region of the n-type channel embedded semiconductor memory device are arsenic ions or antimony ions or phosphorous ions, and the ions implanted into the source/drain extension region of the p-type channel embedded semiconductor memory device are indium ions or boron ions.

19. An embedded semiconductor memory device, comprising:
a semiconductor substrate comprising region I and region II, said region I being a core circuit region and including region i and region ii, said region II being an IO (Input and Output) circuit region and including region iii and region iv;
the gate dielectric layers and the gate structures formed sequentially on the semiconductor substrate;
the source/drain extension regions formed respectively in region I and region II; and
the source/drain regions formed respectively in region I and region II, wherein upon application of a voltage to the gate structures, the respective source/drain regions are connected electrically through conductive channels formed in the semiconductor substrate, wherein the gate dielectric layer in region i and/or region iii is a charge trap region, and the gate dielectric layer in region ii and/or region iv is a non-charge trap region.

20. The embedded semiconductor memory device according to claim 19, wherein the gate dielectric layers are high-k dielectric materials, such as HfO₂, Al₂O₃, La₂O₃, HfSiON or HfAlO₂, with charge traps therein, the gate dielectric layer in region ii and/or region iv forms a non-charge trap region by a first ion implantation and/or a second ion implantation to eliminate the charge traps, and the gate dielectric layer in region i and/or region iii forms a charge trap region.

21. The embedded semiconductor memory device according to claim 20, wherein the ions for the first ion implantation and/or the second ion implantation are fluorine ions or nitrogen ions, the implantation energy for the first ion implantation and/or the second ion implantation is determined in accordance with the implanted ions and thickness of the gate structures, and the implantation dosage for the first ion implantation and/or the second ion implantation ranges from 1.0E+11 to 1.0E+15 cm⁻².

22. The embedded semiconductor memory device according to claim 19, wherein the gate dielectric layers comprising silicon oxide, silicon nitride or a combination thereof, the gate dielectric layers in region i and/or region iii forms a charge trap region by a first ion implantation and/or a second ion implantation to eliminate the charge traps, and the gate dielectric layers in region ii and/or region iv forms a non-charge trap region.

23. The embedded semiconductor memory device according to claim 22, wherein ions for the first ion implantation and/or the second ion implantation are silicon ions, germanium ions, nitrogen ions or hafnium ions, the implantation dosage for the first ion implantation and/or the second ion implantation ranges from 1.0E+11 to 1.0E+13 cm⁻², the implantation energy for the first ion implantation and/or the second ion implantation is determined in accordance with the implanted ions and thickness of the gate structures, and the implantation for the first ion implantation and/or the second ion implantation ranges from 0° to 60°.

24. The embedded semiconductor memory device according to claim 19, wherein the channel of an embedded semiconductor memory device is an n-type or a p-type, the ions implanted into the source/drain extension region of the n-type channel embedded semiconductor memory device are arsenic ions or antimony ions or phosphorous ions, and the ions implanted into the source/drain extension region of the p-type channel embedded semiconductor memory device are indium ions or boron ions.
